(19) United States
(12) Patent Application Publication
(10) Pub. No.: US 2025/0158593 A1
(43) Pub. Date: May 15, 2025

(54) ACOUSTIC WAVE DEVICE AND FILTER DEVICE

(71) Applicant: Murata Manufacturing Co., Ltd., Nagaokakyo-shi (JP)

(72) Inventors: Kentaro NAKAMURA, Nagaokakyo-shi (JP); Takuya YABU, Nagaokakyo-shi (JP)

(21) Appl. No.: 19/024,548

(22) Filed: Jan. 16, 2025

Related U.S. Application Data
(63) Continuation of application No. PCT/JP2023/026613, filed on Jul. 20, 2023.

(30) Foreign Application Priority Data
Aug. 4, 2022 (JP) 2022-125004

(51) Int. Cl. H03H 9/13; H03H 9/02; H03H 9/56

(52) U.S. Cl. CPC H03H 9/132; H03H 9/02015; H03H 9/02228; H03H 9/568

(57) ABSTRACT

An acoustic wave device includes a piezoelectric substrate including a piezoelectric layer, and an IDT electrode on the piezoelectric layer. The IDT electrode includes first and second electrode fingers with a circular arc or an elliptical arc shape. When a virtual line connecting tip ends of the second electrode fingers is a first envelope, a virtual line connecting tip ends of the first electrode fingers is a second envelope, and a center of a circle including the circular arc or a midpoint of focal points of an ellipse including the elliptical arc of the first and second electrode fingers is a fixed point, a straight line connecting the fixed point and the tip end of the second electrode finger is not parallel to the first envelope, and a straight line connecting the fixed point and the tip end of the first electrode finger is not parallel to the second envelope.

### CROSS REFERENCE TO RELATED APPLICATIONS

This application claims the benefit of priority to Japanese Patent Application No. 2022-125004 filed on Aug. 4, 2022 and is a Continuation application of PCT Application No. PCT/JP2023/026613 filed on Jul. 20, 2023. The entire contents of each application are hereby incorporated herein by reference.

### BACKGROUND OF THE INVENTION

### 1. Field of the Invention

The present invention relates to acoustic wave devices and filter devices.

### 2. Description of the Related Art

In the related art, acoustic wave devices are widely used for, for example, filters of mobile phones. International Publication No. 2011/108229 discloses an example of an acoustic wave device. In the acoustic wave device, an interdigital transducer (IDT) electrode is provided on a piezoelectric substrate. The shape of a plurality of electrode fingers of the IDT electrode includes a curved shape. More specifically, each electrode finger extends along a curve from the center of a region where the IDT electrodes intersect to a common electrode.

### SUMMARY OF THE INVENTION

In an IDT electrode of an acoustic wave device described in International Publication No. 2011/108229, an electrode finger pitch in the central portion in the direction in which a plurality of electrode fingers extend is narrower than an electrode finger pitch at an end portion in the direction. Therefore, there is an effect of suppressing the response of the unnecessary wave to a certain degree. However, it is impossible to sufficiently reduce or prevent an unnecessary wave outside a pass band or a transverse mode.

Example embodiments of the present invention provide acoustic wave devices and filter devices each capable of sufficiently reducing or preventing an unnecessary wave outside a pass band and a transverse mode.

An acoustic wave device according to an example embodiment of the present invention includes a piezoelectric substrate including a piezoelectric layer, and an IDT electrode on the piezoelectric layer, wherein the IDT electrode includes a first busbar and a second busbar facing each other, a plurality of first electrode fingers of which one end portion is connected to the first busbar, and a plurality of second electrode fingers of which one end portion is connected to the second busbar, and the plurality of first electrode fingers and the plurality of second electrode fingers are interdigitated with each other, shapes of the plurality of first electrode fingers and the plurality of second electrode fingers in a plan view include a shape of a circular arc or an elliptical arc, and when a virtual line formed by connecting tip ends of the plurality of second electrode fingers is defined as a first envelope, a virtual line formed by connecting tip ends of the plurality of first electrode fingers is defined as a second envelope, and a center of a circle including the circular arc or a midpoint of two focal points of an ellipse including the elliptical arc in the shapes of the first electrode fingers and the second electrode fingers is defined as a fixed point, a straight line connecting the fixed point and a tip end of a second electrode finger is not parallel to the first envelope, and a straight line connecting the fixed point and a tip end of a first electrode finger is not parallel to the second envelope.

A filter device according to an example embodiment of the present invention includes a plurality of acoustic wave resonators, in which at least one of the acoustic wave resonators is the acoustic wave device according to the above-described example embodiment of the present invention.

According to the acoustic wave devices and the filter devices according to example embodiments of the present invention, it is possible to sufficiently reduce or prevent the unnecessary wave outside the pass band and the transverse mode.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a schematic plan view of an acoustic wave device according to a first example embodiment of the present invention.

FIG. 2 is a schematic cross-sectional view taken along line I-I in FIG. 1.

FIG. 3 is a schematic plan view for describing a configuration of an IDT electrode in the first example embodiment of the present invention.

FIG. 4 is a schematic plan view of an IDT electrode in a comparative example.

FIG. 5 is a graph showing impedance frequency characteristics in the first example embodiment and the comparative example of the present invention.

FIG. 6 is a graph showing phase characteristics in the first example embodiment and the comparative example of the present invention.

FIG. 7 is a graph showing reverse-velocity surfaces of acoustic waves propagating in a first piezoelectric substrate and a second piezoelectric substrate.

FIG. 8 is a graph showing reverse-velocity surfaces of a longitudinal wave, a fast transversal wave, and a slow transversal wave in the first piezoelectric substrate.

FIG. 9 is a graph showing a relationship between an absolute value of an excitation angle |θ_{C_prop}| and a duty ratio of the IDT electrode in the first example embodiment, a first modification example, and a second modification example of the present invention.

FIG. 10 is a schematic plan view of an acoustic wave device according to a third modification example of the first example embodiment of the present invention.

FIG. 11 is a graph showing phase characteristics in the vicinity of a resonant frequency in the first example embodiment, the third modification example, and the comparative example of the present invention.

FIG. 12 is a graph showing phase characteristics on a lower band side than a resonant frequency in the first example embodiment, the third modification example, and the comparative example of the present invention.

FIG. 13 is a graph showing phase characteristics on a higher band side than the anti-resonant frequency in the first example embodiment, the third modification example, and the comparative example of the present invention.

FIG. 14 is a schematic elevational cross-sectional view of an acoustic wave device according to a fourth modification example of the first example embodiment of the present invention.

FIG. 15 is a schematic elevational cross-sectional view of an acoustic wave device according to a fifth modification example of the first example embodiment of the present invention.

FIG. 16 is a schematic plan view of an acoustic wave device according to a second example embodiment of the present invention.

FIG. 17 is a schematic plan view for describing a configuration of an IDT electrode in the second example embodiment of the present invention.

FIG. 18 is a graph showing a relationship between an absolute value of an excitation angle |θ_{C_prop}| and a rate of change Δpitch of an electrode finger pitch of the IDT electrode in the second example embodiment of the present invention.

FIG. 19 is a schematic plan view of an acoustic wave device according to a third example embodiment of the present invention.

FIG. 20 is a schematic plan view of an acoustic wave device according to a fourth example embodiment of the present invention.

FIG. 21 is a graph showing a relationship between an absolute value of an excitation angle |θ_{C_prop}| and a thickness of an electrode finger of an IDT electrode in the fifth example embodiment of the present invention.

FIG. 22 is a schematic elevational cross-sectional view of an acoustic wave device according to a sixth example embodiment of the present invention.

FIG. 23 is a graph showing a relationship between an absolute value of an excitation angle |θ_{C_prop}| in an excitation portion of an IDT electrode covered with a dielectric film and a thickness of the dielectric film in the sixth example embodiment of the present invention.

FIG. 24 is a graph showing a relationship between an absolute value of an excitation angle |θ_{C_prop}| in an excitation portion of the IDT electrode covered with the dielectric film and a thickness of the dielectric film in a modification example of the sixth example embodiment of the present invention.

FIG. 25 is a schematic plan view showing the vicinity of a gap on a first busbar side of an IDT electrode in a seventh example embodiment of the present invention.

FIG. 26 is a schematic plan view showing the vicinity of a gap on a first busbar side of an IDT electrode in a first modification example of the seventh example embodiment of the present invention.

FIG. 27 is a schematic plan view showing the vicinity of a gap on a first busbar side of an IDT electrode in a second modification example of the seventh example embodiment of the present invention.

FIG. 28 is a circuit diagram of a filter device according to an eighth example embodiment of the present invention.

FIG. 29 is a schematic plan view of an acoustic wave device of a reference example.

FIG. 30 is a schematic plan view of a filter device according to a ninth example embodiment of the present invention.

FIG. 31 is a schematic plan view of a filter device according to a modification example of the ninth example embodiment of the present invention.

FIG. 32 is an enlarged schematic plan view showing a portion of an IDT electrode in a sixth modification example of the first example embodiment of the present invention.

FIG. 33 is a schematic elevational cross-sectional view of an acoustic wave device according to a tenth example embodiment of the present invention.

FIG. 34 is a schematic elevational cross-sectional view of an acoustic wave device according to an eleventh example embodiment of the present invention.

FIG. 35 is a schematic elevational cross-sectional view of an acoustic wave device according to a first modification example of the eleventh example embodiment of the present invention.

FIG. 36 is a schematic elevational cross-sectional view of an acoustic wave device according to a second modification example of the eleventh example embodiment of the present invention.

FIG. 37 is a schematic elevational cross-sectional view of an acoustic wave device according to a third modification example of the eleventh example embodiment of the present invention.

### DETAILED DESCRIPTION OF THE EXAMPLE EMBODIMENTS

Hereinafter, the present invention will be elucidated by describing specific example embodiments of the present invention with reference to the drawings.

Each example embodiment described in the present specification is merely an example, and configurations can be partially replaced or combined with each other between different example embodiments.

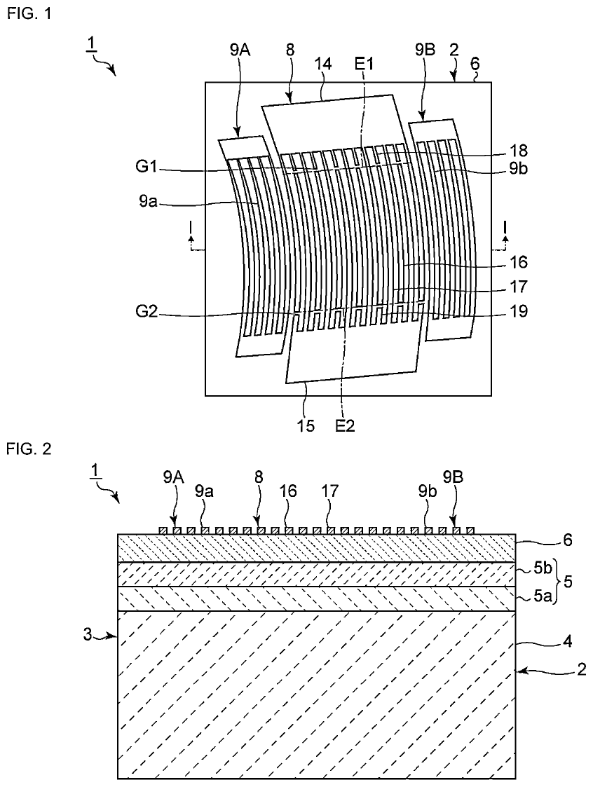

FIG. 1 is a schematic plan view of an acoustic wave device according to a first example embodiment of the present invention. FIG. 2 is a schematic cross-sectional view taken along line I-I in FIG. 1.

As shown in FIGS. 1 and 2, an acoustic wave device 1 includes a piezoelectric substrate 2. The piezoelectric substrate 2 is a substrate having piezoelectricity. Specifically, as shown in FIG. 2, the piezoelectric substrate 2 includes a support 3 and a piezoelectric layer 6. More specifically, the support 3 includes a support substrate 4 and an intermediate layer 5. The intermediate layer 5 includes a first layer 5a and a second layer 5b. The first layer 5a is provided on the support substrate 4. The second layer 5b is provided on the first layer 5a. The piezoelectric layer 6 is provided on the second layer 5b. A layer configuration of the piezoelectric substrate 2 is not limited to the above-described example. For example, the intermediate layer 5 may be a single layer dielectric film. Alternatively, the piezoelectric substrate 2 may be a substrate including only the piezoelectric layer 6.

As shown in FIG. 1, the IDT electrode 8 is provided on the piezoelectric layer 6. The IDT electrode 8 includes a plurality of first electrode fingers 16 and a plurality of second electrode fingers 17. In the present example embodiment, the shapes of the plurality of first electrode fingers 16 and the plurality of second electrode fingers 17 in a plan view are the shapes of circular arcs. In the present specification, the plan view means a view from a direction corresponding to an upper side in FIG. 2. In FIG. 2, for example, the piezoelectric layer 6 side is an upper side among the piezoelectric layer 6 side and the support substrate 4 side. The shapes of the plurality of electrode fingers in a plan view may include a curved portion, particularly a shape of a circular arc or an elliptical arc. Hereinafter, details of the configuration of the IDT electrode 8 will be described.

Returning to FIG. 1, the IDT electrode 8 includes a first busbar 14, a second busbar 15, a plurality of first offset electrodes 18, and a plurality of second offset electrodes 19, in addition to the plurality of first electrode fingers 16 and the plurality of second electrode fingers 17. The first busbar 14 and the second busbar 15 face each other. One end portion of each of the plurality of first electrode fingers 16 is connected to the first busbar 14. One end portion of each of the plurality of second electrode fingers 17 is connected to the second busbar 15. The plurality of first electrode fingers 16 and the plurality of second electrode fingers 17 are interdigitated with each other.

Furthermore, one end portion of each of the plurality of first offset electrodes 18 is connected to the first busbar 14. The first electrode finger 16 and the first offset electrode 18 are alternately arranged. Each one end portion of the plurality of second offset electrodes 19 is connected to the second busbar 15. The second electrode finger 17 and the second offset electrode 19 are alternately arranged.

Each of the plurality of first electrode fingers 16, the plurality of second electrode fingers 17, the plurality of first offset electrodes 18, and the plurality of second offset electrodes 19 includes a base end portion and a tip end portion. The base end portions of the first electrode finger 16 and the first offset electrode 18 are portions connected to the first busbar 14. The base end portions of the second electrode finger 17 and the second offset electrode 19 are portions connected to the second busbar 15. The tip end portion of the first electrode finger 16 and the tip end portion of the second offset electrode 19 face each other with a gap G2 interposed therebetween. On the other hand, the tip end portion of the second electrode finger 17 and the tip end portion of the first offset electrode 18 face each other with a gap G1 interposed therebetween.

Hereinafter, the first electrode finger 16 and the second electrode finger 17 may be simply referred to as an electrode finger. The first offset electrode 18 and the second offset electrode 19 may be simply referred to as an offset electrode. The first busbar 14 and the second busbar 15 may be simply described as a busbar. The pitch or duty ratio of the offset electrode may be different from, for example, the electrode finger pitch or duty ratio of the IDT electrode 8 in the intersection region described later.

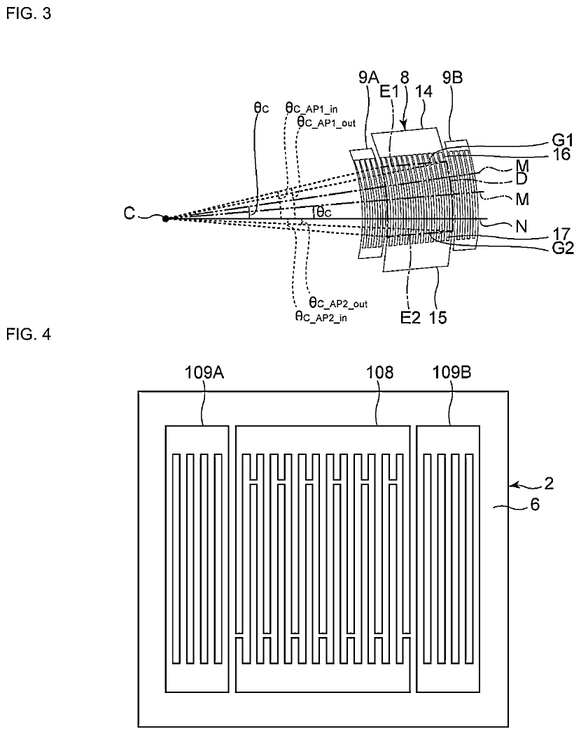

FIG. 3 is a schematic plan view for describing a configuration of the IDT electrode in the first example embodiment. A virtual line formed by connecting the tip ends of the plurality of second electrode fingers is defined as a first envelope E1, and a virtual line formed by connecting the tip ends of the plurality of first electrode fingers is defined as a second envelope E2. A region between the first envelope E1 and the second envelope E2 is an intersection region D. More specifically, a region surrounded by one end electrode finger, the other end electrode finger of the plurality of electrode fingers in a direction in which the plurality of electrode fingers are arranged, the first envelope E1, and the second envelope E2 is the intersection region D. Therefore, the first envelope E1 corresponds to an end edge portion of the intersection region D on the first busbar 14 side. The second envelope E2 corresponds to an end edge portion of the intersection region D on the second busbar 15 side. In the intersection region D, when viewed in the extending direction of the first envelope E1 or the second envelope E2, adjacent electrode fingers overlap each other.

The shapes of the plurality of electrode fingers in a plan view are respective shapes corresponding to the circular arcs of a plurality of concentric circles. Therefore, the centers of the circles including the circular arcs in the shapes of the plurality of electrode fingers match or substantially match each other.

When an elliptical coefficient of the circles or the ellipses including the arcs in the shapes of the plurality of electrode fingers is defined as α2/α1, the elliptical coefficient α2/α1 is 1, for example, in the present example embodiment. In a case where the shapes including the arcs in the shapes of the plurality of electrode fingers are the ellipses, the elliptical coefficient α2/α1 is other than 1, for example. The term α1 corresponds to a dimension along a direction of an axis passing through the intersection region D of the major axis and the minor axis of the ellipse. The term α2 corresponds to a dimension along a direction of an axis that does not pass through the intersection region D of the major axis and the minor axis of the ellipse. When r is an optional constant, the expression of the elliptical coefficient in the XY plane can be represented as (x/α1)²+ (y/α2)²=r².

When the center of the circle including the circular arcs in the shapes of the plurality of electrode fingers is defined as the fixed point C, in the present example embodiment, neither the extension line of the first envelope E1 nor the extension line of the second envelope E2 passes through the fixed point C. Therefore, the straight line passing through the fixed point C and the first envelope E1 is not parallel to the first envelope E1. Similarly, the straight line passing through the fixed point C and the second envelope E2 is not parallel to the second envelope E2.

As a material of the piezoelectric layer 6 of the acoustic wave device 1, a piezoelectric single crystal may be used, for example. In the piezoelectric layer 6, the propagation axis is the direction of X propagation. In the present example embodiment, among straight lines passing through the intersection region D and the fixed point C, a straight line extending parallel to the propagation axis is the reference line N. However, the reference line N need not necessarily extend for parallel substantially parallel to the propagation axis.

The propagation axis may be not only the direction of X propagation, but also a direction perpendicular to either the direction of 90° X propagation or the direction in which the electrode finger of the IDT electrode 8 extends. The direction in which the electrode fingers extend herein refers to a direction in which the tangent line of each portion of the electrode fingers extends. The direction in which the acoustic wave is excited is a direction perpendicular to a direction in which a tangent line of each portion of the electrode finger extends, a direction connecting the shortest distance between adjacent electrode fingers, or a direction parallel to an electric field vector generated between the electrode fingers. The direction in which the electrode finger extends herein specifically refers to a direction in which a tangent line of a curve connecting each portion of the electrode finger extends. In addition, each portion of the electrode finger can be represented by the center of gravity or an intermediate point between both ends. In an acoustic wave resonator used in the related art shown in FIG. 4, the excitation direction of the acoustic wave is the same in any definition. In a case where the curve is a circular arc centered at the fixed point C, the direction in which the acoustic wave is excited is represented by a direction perpendicular to a direction in which the tangent line of the curve connecting each portion of the electrode fingers extends.

An angle formed between the straight line passing through the fixed point C and the reference line N is defined as θ_{C}. Although there are an infinite number of straight lines passing through the fixed point C, FIG. 3 shows an example of the straight line. In the present specification, a positive direction of the angle θ_{C} is a counterclockwise direction when viewed in a plan view. More specifically, a direction from the second busbar 15 side toward the first busbar 14 side is the positive direction.

By applying an AC voltage to the IDT electrode 8, an acoustic wave is excited in the intersection region D. The intersection region D has each portion located on an infinite number of straight lines passing through the fixed point C. In FIG. 3, a straight line M is shown as an example of the infinite number of straight lines passing through the fixed point C and the intersection region D. For example, in a portion located on the straight line M in the intersection region D, the acoustic wave is excited. The acoustic wave is also excited at each of the portions located on the infinite number of straight lines passing through the fixed point C and the intersection region D, which are not shown in the drawing. That is, the acoustic wave device 1 includes an excitation portion located on the straight line M and excitation portions located on an infinite number of straight lines (not shown).

An angle formed between the straight line passing through the fixed point C, the excitation portion, and the reference line N is the angle θ_{C}. In addition, an angle formed between a straight line passing through the fixed point C and the excitation portion in the intersection region D and the excitation direction of the acoustic wave at the intersection of the first electrode finger 16 or the second electrode finger 17, and the reference line N is defined as an excitation angle θ_{C_prop}. In the excitation portion through which the reference line N passes, the angle θ_{C} and the excitation angle θ_{C_prop} are 0°. In each of the excitation portions, the excitation angles θ_{C_prop} are different from each other, and thus the propagation characteristics of the acoustic waves are different from each other. On the other hand, in the present example embodiment, the duty ratios are different from each other between the plurality of excitation portions such that the resonant frequencies or the anti-resonant frequencies of all the excitation portions match or substantially match each other. The duty ratios are the same as each other between the excitation portions having the same absolute value of the excitation angle |θ_{C_prop}|. Since the IDT electrode 8 is configured as described above, the resonance characteristics are unlikely to deteriorate. However, the duty ratio may be constant.

Here, the angle θ_{C} in the excitation portion and the excitation angle θ_{C_prop} match or substantially match each other. Hereinafter, although any one angle of the angle θ_{C} and the excitation angle θ_{C_prop} is taken up and discussed, there is no difference to have an effect that reverses the action and effect. When the elliptical coefficient α2/α1 is 1, for example, that is, in a case of being a circle, the angle θ_{C} and the excitation angle θ_{C_prop} are equal or substantially equal to each other.

In the present specification, the fact that one frequency and the other frequency match or substantially match each other means that the absolute value of the difference between both frequencies is equal to or smaller than about 2% of a reference frequency, for example. The reference frequency is a frequency when the excitation angle θ_{C_prop} is 0°, for example. In the intersection region D, an absolute value of a difference between the highest resonant frequency and the lowest resonant frequency of the main mode is preferably about 18 or less with respect to the reference frequency, for example. Alternatively, in the intersection region D, an absolute value of a difference between the highest anti-resonant frequency and the lowest anti-resonant frequency of the main mode is preferably about 18 or less with respect to the reference frequency, for example.

In the IDT electrode 8 of the acoustic wave device 1, the electrode finger pitch is constant. Therefore, when the wavelength defined by the electrode finger pitch is λ, the wavelength λ in the IDT electrode 8 is constant regardless of the excitation angle θ_{C_prop}. The electrode finger pitch is the center-to-center distance of the first electrode finger 16 and the second electrode finger 17 adjacent to each other. When the electrode finger pitch is p, λ=2p, for example.

An angle θ_{C} formed between a straight line passing through the fixed point C and the end portion of the first envelope E1 on the fixed point C side, and the reference line N is defined as a first inner side portion intersection angle θ_{C_AP1_in}. An angle θ_{C} formed between a straight line passing through the fixed point C and the end portion of the first envelope E1 on the side far from the fixed point C, and the reference line N is defined as a first outer side portion intersection angle θ_{C_AP1_out}. An angle θ_{C} formed between a straight line passing through the fixed point C and the end portion of the second envelope E2 on the fixed point C side, and the reference line N is defined as a second inner side portion intersection angle θ_{C_AP2_in}. An angle θ_{C} formed between a straight line passing through the fixed point C and the end portion of the second envelope E2 on the side far from the fixed point C, and the reference line N is defined as a second outer side portion intersection angle θ_{C_AP2_out}. As described above, in the present example embodiment, the straight line connecting the fixed point C and the tip end of the second electrode finger 17 is not parallel to the first envelope E1. Therefore, θ_{C_AP1_in}≠θ_{C_AP1_out}. Similarly, a straight line connecting the fixed point C and the tip end of the first electrode finger 16 is not parallel to the second envelope E2. Therefore, θ_{C_AP2_in}≠θ_{C_AP2_out}.

In the IDT electrode 8, the first envelope E1 and the first busbar 14 extend parallel or substantially parallel to each other. Similarly, the second envelope E2 and the second busbar 15 extend parallel or substantially parallel to each other. When an angle formed by the reference line N and the busbar is defined as a busbar inclination angle, the busbar inclination angles of the first busbar 14 and the second busbar 15 are the same as each other. However, the busbar inclination angles of the first busbar 14 and the second busbar 15 may be different from each other. In the present specification, a positive direction of the busbar inclination angle is a counterclockwise direction in a plan view.

As shown in FIG. 1, a reflector 9A and a reflector 9B are provided on the piezoelectric layer 6. The reflector 9A and the reflector 9B face each other with the IDT electrode 8 interposed therebetween in an arrangement direction of the plurality of electrode fingers of the IDT electrode 8. The reflector 9A includes a plurality of electrode fingers 9a. The reflector 9B includes a plurality of electrode fingers 9b. In a plan view, the shapes of the plurality of electrode fingers 9a of the reflector 9A and the shapes of the plurality of electrode fingers 9b of the reflector 9B correspond to the respective shapes of the circular arcs of the plurality of concentric circles. The center of the circle including the circular arcs in the shapes of the plurality of electrode fingers 9a and the plurality of electrode fingers 9b matches or substantially matches the fixed point C. The shape of the electrode finger of each reflector may be a shape of a curve or a straight line different from the shape of the electrode finger of the IDT electrode 8 in the excitation portion. The structural parameters such as the electrode finger pitch or the duty ratio of each reflector may be different from the structural parameters of the electrode finger of the IDT electrode 8 in the excitation portion. The electrode fingers of each reflector may be configured in a pattern different from the shape of the electrode finger of the IDT electrode 8 in the excitation portion.

A unique feature of the present example embodiment is that the acoustic wave device 1 has the following configuration. 1) The shapes of the plurality of electrode fingers in a plan view include the shapes of the circular arcs or the elliptical arcs. 2) A straight line connecting the fixed point C and the tip end of the second electrode finger 17 is not parallel to the first envelope E1, and a straight line connecting the fixed point C and the tip end of the first electrode finger 16 is not parallel to the second envelope E2. As a result, it is possible to sufficiently reduce or prevent the unnecessary wave outside the pass band and the transverse mode. In the present specification, the outside of the pass band in the acoustic wave device refers to a lower band side than the resonant frequency and a higher band side than the anti-resonant frequency. Details of the above-described effects will be described below by comparing the present example embodiment with a comparative example.

In the comparative example, as shown in FIG. 4, each of the electrode fingers of the IDT electrode 108, the reflector 109A, and the reflector 109B is linear. In the IDT electrode 108, the intersection region is rectangular or substantially rectangular. In the first example embodiment and the comparative example, the impedance frequency characteristics and the phase characteristics were compared. Non-limiting examples of design parameters of the acoustic wave device 1 according to the first example embodiment are as follows. Here, a dimension along a direction connecting the base end portion and the tip end portion of the offset electrode is defined as a length of the offset electrode.
Support Substrate 4: material Si, surface orientation (111), ψ at Euler angles (φ, θ, ψ) 73°
First layer 5a: material SiN, thickness 0.15λ
Second layer 5b: material SiO₂, thickness 0.15λ
Piezoelectric layer 6: material rotation Y-cut 55° X propagation LiTaO₃, thickness 0.2λ
IDT electrode 8: material A1, thickness 0.05λ
Number of pairs of electrode fingers of IDT electrode 8: 60 pairs
Elliptical coefficient α2/α1 in the shape of the electrode finger: 1
First inner side portion intersection angle θ_{C_AP1_in}: 11.1°
First outer side portion intersection angle θ_{C_AP1_out}: 8.6°
Second inner side portion intersection angle θ_{C_AP2_in}: −6.2°
Second outer side portion intersection angle θ_{C_AP2_out}: −3.5°
Wavelength λ: 2 μm
Duty ratio: 0.5 in the excitation portion in which the excitation angle θ_{C_prop} is 0°
Busbar inclination angle of the first busbar 14 and the second busbar 15: 2.5°
Length of the first offset electrode 18 and the second offset electrode 19: 3.5λ
Reflector 9A and reflector 9B: Number of pairs of electrode fingers 20 pairs

On the other hand, when a direction in which the plurality of electrode fingers extend is defined as an electrode finger stretching direction and a dimension of the intersection region along the electrode finger stretching direction is defined as an intersection width, the intersection width in the IDT electrode 108 of the acoustic wave device of the comparative example is 41.5λ. The number of pairs of electrode fingers of the IDT electrode 108 is 60 pairs, and the number of pairs of electrode fingers of each of the reflector 109A and the reflector 109B is 20 pairs. In the IDT electrode 108, the duty ratio is 0.5.

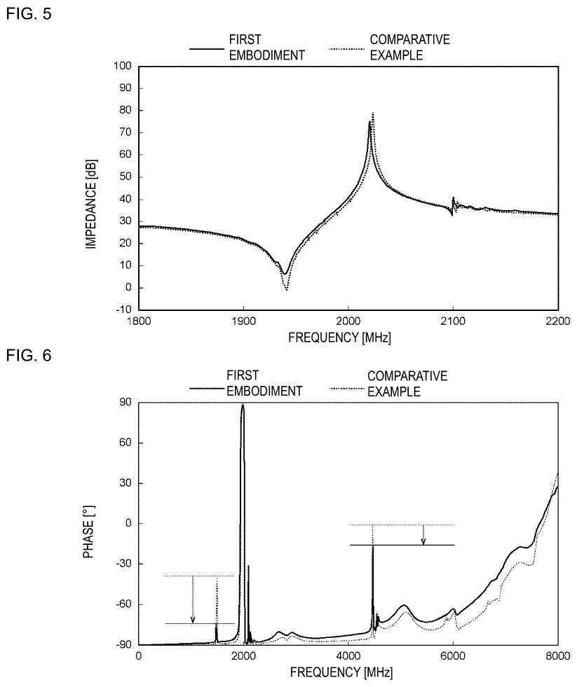

FIG. 5 is a graph showing the impedance frequency characteristics in the first example embodiment and the comparative example. FIG. 6 is a graph showing phase characteristics in the first example embodiment and the comparative example.

As shown in FIG. 5, in the comparative example, a plurality of ripples are generated between the resonant frequency and the anti-resonant frequency. These ripples are caused by the transverse mode. On the other hand, it can be seen that the ripples caused by the transverse mode are reduced or prevented in the first example embodiment. Furthermore, as shown in FIG. 6, it can be seen that the unnecessary wave outside the pass band is reduced or prevented in the first example embodiment as compared with the comparative example. Specifically, in the first example embodiment, the unnecessary wave is reduced or prevented on both the lower band side of the resonant frequency and the higher band side of the anti-resonant frequency. As described above, in the first example embodiment, it is possible to reduce or prevent the unnecessary wave outside the pass band and to suppress the transverse mode.

In an example embodiment of the present invention, the above-described effect is obtained by utilizing the fact that the propagation characteristics of the acoustic wave are different from each other in each of the excitation portions. Details will be described below.

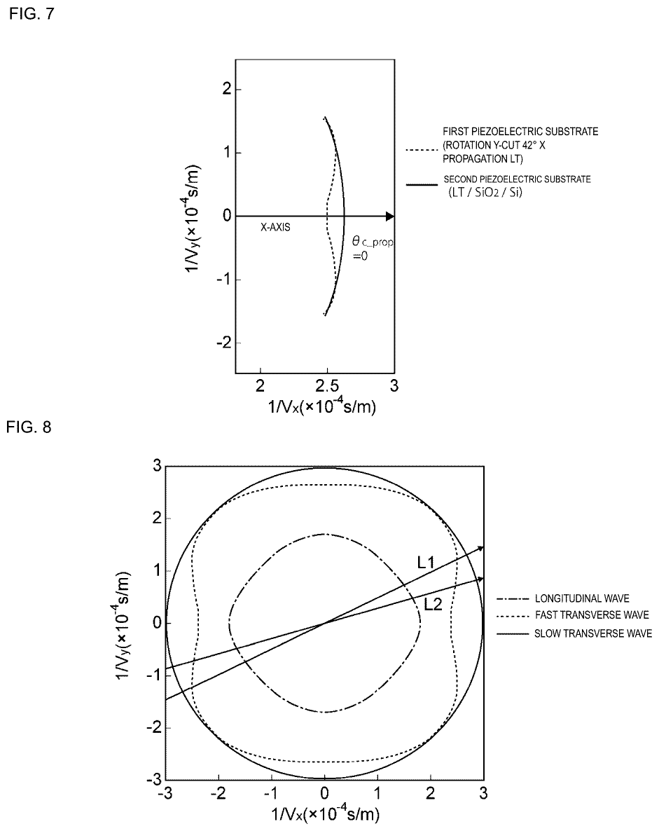

The phase velocity of the acoustic wave has a dependence on the excitation angle θ_{C_prop} and exhibits unique characteristics depending on the configuration of the substrate. The reciprocal of the phase velocity corresponds to the reverse-velocity surface. Therefore, the relationship between the excitation angle θ_{C_prop} and the phase velocity is equal or substantially equal to the reverse-velocity surface of the piezoelectric substrate. Therefore, FIG. 7 shows an example of reverse-velocity surfaces of piezoelectric substrates having different layer configurations. The one piezoelectric substrate is a substrate including only LiTaO₃(LT) of the rotation Y-cut 42° X propagation, for example. This substrate is defined as a first piezoelectric substrate. The other piezoelectric substrate is a bonded substrate of a piezoelectric layer and a support substrate. This substrate is defined as a second piezoelectric substrate. More specifically, the second piezoelectric substrate is a substrate in which a silicon substrate having a surface orientation of (100), a silicon oxide film, and a lithium tantalate layer are laminated in this order. The shape of the unevenness of the reverse-velocity surface does not change even when the surface orientation of the silicon substrate is another surface orientation such as (110) or (111).

FIG. 7 is a graph showing reverse-velocity surfaces of acoustic waves propagating in the first piezoelectric substrate and the second piezoelectric substrate.

The x-axis shown in FIG. 7 corresponds to the result when the x-axis is parallel to the propagation axis. That is, the x-axis corresponds to the result when the excitation angle θ_{C_prop} is 0°. The reverse-velocity surfaces of the first piezoelectric substrate and the second piezoelectric substrate are both line-symmetrical with the x-axis as a symmetry axis. The reverse-velocity surface in the first piezoelectric substrate has a recessed shape. On the other hand, the reverse-velocity surface in the second piezoelectric substrate has a projected shape. As described above, it can be seen that the dependence on the excitation angle θ_{C_prop} of the acoustic wave propagating on the substrate varies depending on the configuration of the substrate. Furthermore, in a case where the modes of the acoustic waves are different, the dependence on the excitation angle θ_{C_prop} on the same substrate is different. This is shown in FIG. 8.

FIG. 8 is a graph showing reverse-velocity surfaces of a longitudinal wave, a fast transversal wave, and a slow transversal wave in the first piezoelectric substrate.

As shown in FIG. 8, the reverse-velocity surfaces of a longitudinal wave, a fast transversal wave, and a slow transversal wave, which are three modes of acoustic waves, are different from each other. Each of the portions passing through the arrows L1 and L2 in FIG. 8 corresponds to an example of the result in a case where the excitation angle θ_{C_prop} is other than 0°. An interval between the reverse-velocity surfaces of the slow transversal wave and the fast transversal wave in the portion passing through the arrow L1 and an interval between the reverse-velocity surfaces of the slow transversal wave and the fast transversal wave in the portion passing through the arrow L2 are different from each other. Similarly, an interval between the reverse-velocity surfaces of the fast transversal wave and the longitudinal wave in the portion passing through the arrow L1 and an interval between the reverse-velocity surfaces of the fast transversal wave and the longitudinal wave in the portion passing through the arrow L2 are different from each other. That is, in the excitation portions having different excitation angles θ_{C_prop}, the intervals between the reverse-velocity surfaces of different modes are different. The same applies to a relationship between the main mode used in the acoustic wave device and the unnecessary wave.

In this case, in the acoustic wave device 1 according to the first example embodiment, the resonant frequencies or the anti-resonant frequencies of the main mode match or substantially match each other in all the excitation portions. Therefore, in the different excitation portions, the frequencies of the unnecessary waves are different from each other. As a result, each of the unnecessary wave outside the pass band and the transverse mode is dispersed. Therefore, it is possible to reduce or prevent the unnecessary wave outside the pass band and the transverse mode.

In the first example embodiment, since the resonant frequencies or the anti-resonant frequencies in each of the excitation portions match or substantially match each other, the main mode is suitably excited. Therefore, deterioration of the resonance characteristics can be reduced or prevented.

In addition, in the first example embodiment, the first inner side portion intersection angle θ_{C_AP1_in} and the first outer side portion intersection angle θ_{C_AP1_out} are different from each other. The second inner side portion intersection angle θ_{C_AP2_in} and the second outer side portion intersection angle θ_{C_AP2_out} are different from each other. Therefore, in each of the electrode fingers, the ranges of the excitation angles θ_{C_prop} of the excitation portion including the electrode finger are different from each other. For example, in the acoustic wave device 1 of the first example embodiment related to the comparison of FIGS. 5 and 6, the excitation angle θ_{C_prop} of the excitation portion including the electrode finger closest to the fixed point C side among the plurality of electrode fingers is about −6.2° or more and about 11.1° or less, for example. On the other hand, the excitation angle θ_{C_prop} of the excitation portion including the electrode finger on the side farthest from the fixed point C among the plurality of electrode fingers is about −3.5° or more and about 8.6° or less, for example. Similarly, the ranges of the excitation angles θ_{C_prop} of the excitation portion including each of the electrode fingers are different from each other.

As described above, in the excitation portions having different excitation angles θ_{C_prop}, the intervals between reverse-velocity surfaces of the main mode and the unnecessary wave are different. However, in the first example embodiment, the resonant frequencies or the anti-resonant frequencies of the main mode match or substantially match each other in all the excitation portions. In the first example embodiment, the ranges of the excitation angles θ_{C_prop} of the excitation portions including each electrode finger are different from each other. Therefore, the range of variation in the frequency of the excited unnecessary wave varies for respective portions in which the electrode fingers are located. Therefore, the unnecessary wave can be effectively dispersed. Therefore, it is possible to effectively reduce or prevent the unnecessary wave outside the pass band and the transverse mode.

Hereinafter, the fact that the resonant frequencies in the main mode match or substantially match each other will be described in detail. As described above, the phase velocity corresponds to the reciprocal of the reverse-velocity surface. Therefore, the relationship between the excitation angle θ_{C_prop} and the phase velocity is equal or substantially equal to the reverse-velocity surface of the piezoelectric substrate in the XY plane as shown in FIG. 8. That is, it can be said that the function representing the curved shape of the electrode finger is determined by the shape of the reverse-velocity surface of the piezoelectric substrate in the XY plane. The phase velocity of the acoustic wave has a dependence on the excitation angle θ_{C_prop}.

However, when the shape of the electrode finger is simply made to be curved, the impedance frequency characteristics are obtained by superimposing the characteristics in which the resonant frequencies at each of the excitation angles θ_{C_prop} are significantly different from each other. Therefore, the impedance frequency characteristics significantly deteriorate. Therefore, as in the first example embodiment, by changing the duty ratio that affects the frequency according to the excitation angle θ_{C_prop}, the frequencies of the acoustic waves excited at each of the excitation angles θ_{C_prop} can match or substantially match each other. Therefore, in each of the excitation portions, the resonant frequencies can match or substantially match each other. In each of the excitation portions, the anti-resonant frequencies can also match or substantially match each other. Therefore, the impedance frequency characteristics are obtained in which the resonant frequencies or the anti-resonant frequencies match or substantially match each other.

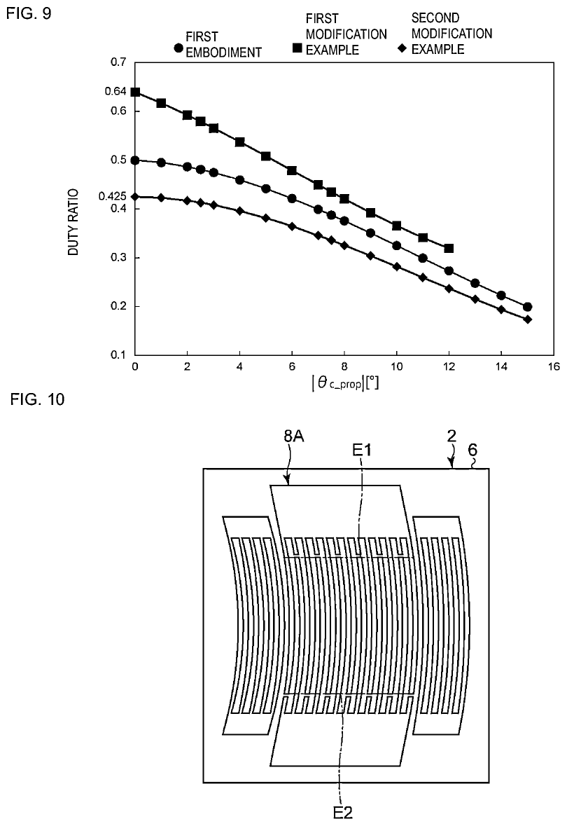

In the first example embodiment, a relationship between the excitation angle θ_{C_prop} and the duty ratio is described in FIG. 9. An example in which the maximum value of the duty ratio is different from that of the first example embodiment is also described as a first modification example and a second modification example of the first example embodiment.

FIG. 9 is a graph showing a relationship between an absolute value of an excitation angle |θ_{C_prop}| and a duty ratio of the IDT electrode in the first example embodiment, the first modification example, and the second modification example.

In the first example embodiment, in a case where the excitation angle θ_{C_prop} is 0°, the duty ratio is at a maximum value, for example. That is, in the first example embodiment, the straight line passing through the excitation portion having the largest duty ratio and the fixed point C among all the excitation portions is the reference line N. In the first example embodiment, when the excitation angle θ_{C_prop} is 0°, the duty ratio is about 0.5, for example. The larger the absolute value of the excitation angle |θ_{C_prop}|, the smaller the duty ratio. As a result, the resonant frequencies or the anti-resonant frequencies match or substantially match each other in all the excitation portions.

Even in the first modification example and the second modification example, the larger the absolute value of the excitation angle | θ_{C_prop}|, the smaller the duty ratio. In the first modification example, the duty ratio is about 0.64 when the excitation angle θ_{C_prop} is 0°, for example. In the second modification example, the duty ratio is about 0.425 when the excitation angle θ_{C_prop} is 0°, for example. In the first modification example and the second modification example, the resonant frequencies or the anti-resonant frequencies match or substantially match each other in all the excitation portions. In addition, in the first modification example and the second modification example, the configuration is the same as that of the first example embodiment except for the duty ratio. Therefore, it is possible to reduce or prevent the unnecessary wave outside the pass band and the transverse mode.

Incidentally, a semiconductor lithography method may be used for forming the IDT electrode 8, for example. When a resist and a metal wire pattern are formed using the semiconductor lithography method, and the duty ratio is less than about 0.2 or more than about 0.8, for example, it is not easy to form a pattern, and it is difficult to perform stable pattern processing with small manufacturing variations. According to FIG. 9, the larger the duty ratio when the excitation angle θ_{C_prop} is 0°, the larger the duty ratio when the absolute value of the excitation angle |θ_{C_prop}| is increased. That is, as the duty ratio when OC prop is 0° is large, a curve pattern in which the absolute value of the excitation angle |θ_{C_prop}| is large can be formed. In the curve pattern in a range where the absolute value of the excitation angle |θ_{C_prop}| is large, the effect of reducing or preventing the unnecessary wave is further enhanced. From these facts, the duty ratio of the electrode fingers of the IDT electrode 8 is preferably in a range of about 0.2 or more and about 0.8 or less, and more preferably in a range of about 0.25 or more and about 0.75 or less, for example. In addition, it is desirable that the duty ratio when the excitation angle θ_{C_prop} is 0° is about 0.5 rather than about 0.425, and it is more desirable that the duty ratio is about 0.64 rather than about 0.5, for example.

The relationship between the duty ratio and the frequency of each mode varies depending on the reverse-velocity surface of the piezoelectric substrate. Therefore, depending on the configuration of the piezoelectric substrate e or the configuration on the piezoelectric substrate, when the larger the absolute value of the excitation angle |θ_{C_prop}|, the larger the duty ratio, the resonant frequencies or the anti-resonant frequencies may match or substantially match each other in all the excitation portions. In this case, among all the excitation portions, a straight line passing through the excitation portion having the smallest duty ratio and the fixed point C is the reference line N. Examples thereof include an acoustic wave device in which an IDT electrode provided on a substrate including only LiNbO₃ having a rotation Y-cut−4° X propagation is embedded in a SiO₂ film having a thick thickness. Alternatively, in the excitation portion in which the reference line N passes and the excitation angle θ_{C_prop} is 0°, the duty ratio is not necessarily maximum or minimum.

In the first example embodiment shown in FIG. 1, the first envelope E1 and the second envelope E2 are inclined with respect to the direction in which the reference line N extends. However, the present invention is not limited thereto. In the IDT electrode 8A of the third modification example of the first example embodiment shown in FIG. 10, the first envelope E1 and the second envelope E2 extend parallel or substantially parallel to the reference line N. Both the inclination angles of the first busbar and the second busbar are 0°.

However, as in the first example embodiment shown in FIG. 1, it is preferable that the first busbar 14 and the second busbar 15 are inclined with respect to the reference line N. As a result, the transverse mode can be effectively reduced or prevented. This fact will be shown by comparing the first example embodiment, the third modification example, and the comparative example shown in FIG. 4.

Non-limiting examples of the design parameters of the acoustic wave devices of the first example embodiment and the comparative example are the same as those in the comparison in FIGS. 5 and 6. Non-limiting examples of the design parameters of the acoustic wave device of the third modification example are the same as the design parameters of the acoustic wave device 1 of the first example embodiment except for the following points.
First inner side portion intersection angle θ_{C_AP1_in}: 8.5°
First outer side portion intersection angle θ_{C_AP1_out}: 6°
Second inner side portion intersection angle θ_{C_AP2_in}: −8.5°
Second outer side portion intersection angle θ_{C_AP2_out}: −6°
Busbar inclination angle of the first busbar and the second busbar: 0°

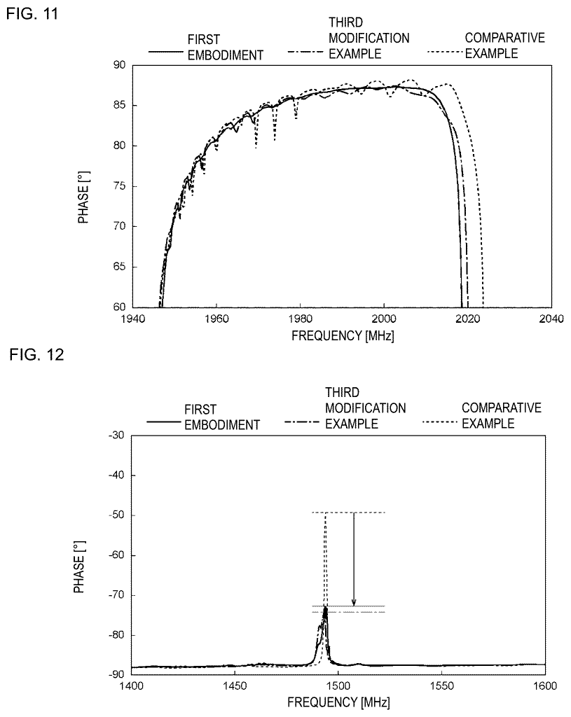

FIG. 11 is a graph showing phase characteristics in the vicinity of a resonant frequency in the first example embodiment, the third modification example, and the comparative example.

As shown in FIG. 11, in the comparative example, a large ripple caused by the transverse mode is generated in the vicinity of about 1950 MHz to about 2010 MHz, for example. On the other hand, in the third modification example, the ripple caused by the transverse mode is small. Furthermore, it can be seen that in the first example embodiment, the ripple caused by the transverse mode is suppressed as compared with the third modification example. As described above, since the first busbar and the second busbar are inclined with respect to the reference line N, the transverse mode can be effectively suppressed. More specifically, in the first example embodiment, this fact is because the first busbar and the second busbar are inclined with respect to the reference line N, and the first inner side portion intersection angle θ_{C_AP1_in} and the second inner side portion intersection angle θ_{C_AP2_in} are different from each other. Furthermore, the reason is that the first outer side portion intersection angle θ_{C_AP1_out} and the second outer side portion intersection angle θ_{C_AP2_out} are different from each other.

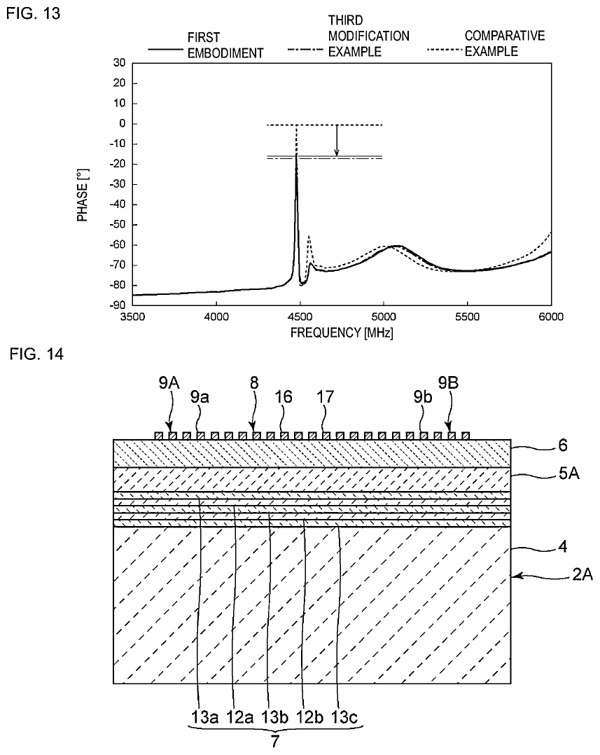

FIG. 12 is a graph showing phase characteristics on a lower band side than the resonant frequency in the first example embodiment, the third modification example, and the comparative example. FIG. 13 is a graph showing phase characteristics on a higher band side than the anti-resonant frequency in the first example embodiment, the third modification example, and the comparative example.

As shown in FIG. 12, it can be seen that in the first example embodiment and the third modification example, the unnecessary waves on the lower band side than the resonant frequency can be reduced or prevented as compared with the comparative example. As shown in FIG. 13, it can be seen that in the first example embodiment and the third modification example, the unnecessary waves on the higher band side than the anti-resonant frequency can be reduced or prevented as compared with the comparative example. As described above, even in the third modification example, it is possible to reduce or prevent the unnecessary wave outside the pass band and the transverse mode, similar to the first example embodiment.

Returning to FIG. 1, the shapes of the plurality of first offset electrodes 18 and the shapes of the plurality of second offset electrodes 19 in the first example embodiment are the respective shapes corresponding to the circular arcs of the plurality of concentric circles. The center of the circle including the circular arcs in the shapes of the plurality of first offset electrodes 18 and the plurality of second offset electrodes 19 matches or substantially matches the fixed point C. However, in a case where the shapes of the plurality of electrode fingers in a plan view are the shapes of the elliptical arcs, the shapes of the plurality of first offset electrodes 18 and the plurality of second offset electrodes 19 may be the shapes of the elliptical arcs included in the ellipse having the focal point with the fixed point C as the midpoint. The center of the two focal points is the center of gravity of the two focal points, and is the center of gravity of the ellipse having the two focal points. Therefore, in a case where the shape of the electrode finger of the IDT electrode or the offset electrode in a plan view is the shape of an elliptical arc, the fixed point C is the center of gravity of the ellipse including the elliptical arc.

In the IDT electrode 8, the duty ratio is changed in the region between the intersection region D and the first busbar 14 and the region between the intersection region D and the second busbar 15, similar to the intersection region D. Therefore, the duty ratio of the portion including the first offset electrode 18 on the extension line of any excitation portion and the excitation portion is constant. Similarly, the duty ratio of a portion including the second offset electrode 19 on the extension line of any excitation portion and the excitation portion is constant.

However, in the first example embodiment, focusing on the region between the first busbar 14 and the intersection region D, the closer to the first busbar 14 in the region, the larger the duty ratio. Similarly, in the region between the second busbar 15 and the intersection region, the closer to the second busbar 15, the larger the duty ratio.

The shapes of the plurality of first offset electrodes 18 and the plurality of second offset electrodes 19 are not limited to the above-described shapes. For example, in the region between the first busbar 14 and the intersection region D, the closer to the first busbar 14, the smaller the duty ratio may be. In the region between the second busbar 15 and the intersection region D, the closer to the second busbar 15, the smaller the duty ratio may be. Alternatively, the offset electrode need not necessarily be provided. Even in this case, the unnecessary wave can be reduced or prevented in example embodiments of the present invention. Furthermore, the shapes of the first electrode finger 16 and the second electrode finger 17 are not particularly limited in regions other than the intersection region D.

As described above, the tip end portion of the second electrode finger 17 and the tip end portion of the first offset electrode 18 face each other with the gap G1 interposed therebetween. The size of the gap G1 is a distance between the tip end portion of the second electrode finger 17 and the tip end portion of the first offset electrode 18. Similarly, the size of the gap G2 is a distance between the tip end portion of the first electrode finger 16 and the tip end portion of the second offset electrode 19. The sizes of the gap G1 and the gap G2 are desirably about 1λ or less and more desirably about 0.5λ or less, for example. When the gap G1 is larger than about 0.5λ, there is a tendency for the acoustic wave to easily leak from the intersection region D in a direction toward the first busbar 14. The same applies to a case where the gap G2 is larger than about 0.5λ. When the sizes of the gap G1 and the gap G2 exceed 1λ, the amount of leakage of the main mode increases, and the loss may be non-negligible.

In addition, the lengths of the first offset electrode 18 and the second offset electrode 19 are desirably about 1λ or more and more desirably about 1.3λ or more, for example. When the length of the first offset electrode 18 is shorter than about 1.3λ, there is a tendency for the acoustic wave to easily leak from the intersection region D in a direction toward the first busbar 14. The same applies to a case where the length of the second offset electrode 19 is shorter than about 1.3λ. When the lengths of the first offset electrode 18 and the second offset electrode 19 are shorter than about 1λ, the amount of leakage of the main mode increases, and the loss may be non-negligible.

Incidentally, as shown in FIG. 2, in the first example embodiment, the piezoelectric substrate 2 is a laminated substrate including the support substrate 4, the first layer 5a and the second layer 5b of the intermediate layer 5, and the piezoelectric layer 6. More specifically, the first layer 5a in the first example embodiment is a high acoustic velocity film. The high acoustic velocity film is a layer having a relatively high acoustic velocity. More specifically, the acoustic velocity of the bulk wave propagating through the high acoustic velocity film is higher than the acoustic velocity of the acoustic wave propagating through the piezoelectric layer 6. On the other hand, the second layer 5b is a low acoustic velocity film. The low acoustic velocity film is a film having a relatively low acoustic velocity. More specifically, the acoustic velocity of the bulk wave propagating through the low acoustic velocity film is lower than the acoustic velocity of the bulk wave propagating through the piezoelectric layer 6.

In the first example embodiment, in the piezoelectric substrate 2, the high acoustic velocity film, the low acoustic velocity film, and the piezoelectric layer 6 are laminated in this order. As a result, the energy of the acoustic wave can be effectively confined to the piezoelectric layer 6 side.

As the material of the high acoustic velocity film, for example, a media including the following material as a main component, such as silicon, aluminum oxide, silicon carbide, silicon nitride, silicon oxynitride, sapphire, lithium tantalate, lithium niobate, quartz, alumina, zirconia, cordierite, mullite, steatite, forsterite, magnesia, a diamond-like carbon (DLC) film, diamond, spinel, or sialon can be used.

As the material of the low acoustic velocity film, for example, glass, silicon oxide, silicon oxynitride, lithium oxide, tantalum pentoxide, or a material including a compound in which fluorine, carbon, or boron is added to silicon oxide as a main component can be used.

As the material of the piezoelectric layer 6, for example, lithium tantalate, lithium niobate, zinc oxide, aluminum nitride, quartz, or lead zirconate titanate (PZT) can also be used. As the material of the piezoelectric layer 6, it is preferable to use lithium tantalate or lithium niobate.

As a material of the support substrate 4, for example, a piezoelectric body such as aluminum nitride, lithium tantalate, lithium niobate, or quartz, ceramics such as alumina, sapphire, magnesia, silicon nitride, silicon carbide, zirconia, cordierite, mullite, steatite, forsterite, spinel, or sialon, a dielectric such as aluminum oxide, silicon oxynitride, diamond-like carbon (DLC), or diamond, a semiconductor such as silicon, or a material including the above-described material as a main component can be used. The above-described spinel includes an aluminum compound including one or more elements selected from Mg, Fe, Zn, Mn, oxygen, or the like. Examples of the spinel as the examples of the materials of the support substrate 4 and the high acoustic velocity film include MgAl₂O₄, FeAl₂O₄, ZnAl₂O₄, or MnAl₂O₄. Silicon is preferably used as the material of the support substrate 4.

In the present specification, the main component means a component whose occupied ratio exceeds 50% by weight. The material of the main component may exist in any one state of single crystal, polycrystal, and amorphous, or in a mixed state thereof.

The relationship between the acoustic velocities in the first layer 5a and the second layer 5b in the intermediate layer 5 is not limited to the above-described relationship. Furthermore, the layer configuration of the piezoelectric substrate 2 is not limited to the above-described configuration. Hereinafter, a fourth modification example and a fifth modification example of the first example embodiment which are different from the first example embodiment only in the configuration of the piezoelectric substrate 2 will be described. In the fourth modification example and the fifth modification example, it is possible to reduce or prevent the unnecessary wave outside the pass band and the transverse mode, similar to the first example embodiment. Furthermore, the energy of the acoustic wave can be effectively confined to the piezoelectric layer 6 side.

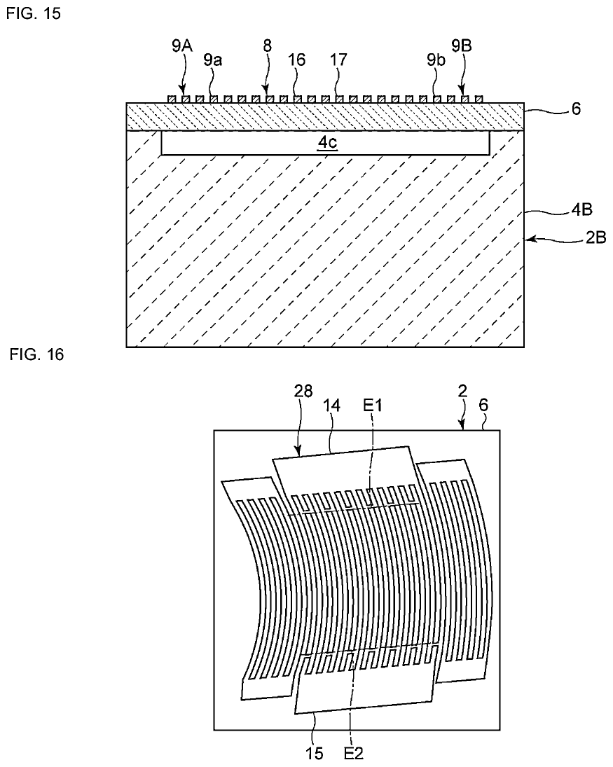

In the fourth modification example shown in FIG. 14, a piezoelectric substrate 2A includes the support substrate 4, an acoustic reflection film 7, an intermediate layer 5A, and the piezoelectric layer 6. The acoustic reflection film 7 is provided on the support substrate 4. The intermediate layer 5A is provided on the acoustic reflection film 7. The piezoelectric layer 6 is provided on the intermediate layer 5A. The intermediate layer 5A is the low acoustic velocity film.

The acoustic reflection film 7 is a multilayer body having a plurality of acoustic impedance layers. Specifically, the acoustic reflection film 7 includes a plurality of low acoustic impedance layers and a plurality of high acoustic impedance layers. The high acoustic impedance layer is a layer having a relatively high acoustic impedance. More specifically, the plurality of high acoustic impedance layers of the acoustic reflection film 7 are a high acoustic impedance layer 13a, a high acoustic impedance layer 13b, and a high acoustic impedance layer 13c. On the other hand, the low acoustic impedance layer is a layer having a relatively low acoustic impedance. More specifically, the plurality of low acoustic impedance layers of the acoustic reflection film 7 are a low acoustic impedance layer 12a and a low acoustic impedance layer 12b. The low acoustic impedance layer and the high acoustic impedance layer are alternately laminated. The high acoustic impedance layer 13a is a layer located closest to the piezoelectric layer 6 side in the acoustic reflection film 7.

The acoustic reflection film 7 includes two low acoustic impedance layers and three high acoustic impedance layers. However, the acoustic reflection film 7 may include at least one low acoustic impedance layer and at least one high acoustic impedance layer.

As a material of the low acoustic impedance layer, for example, silicon oxide or aluminum can be used. As a material of the high acoustic impedance layer, for example, metal such as platinum or tungsten, or a dielectric such as aluminum nitride or silicon nitride can be used. The material of the intermediate layer 5A may be the same as the material of the low acoustic impedance layer.

In the fifth modification example shown in FIG. 15, a piezoelectric substrate 2B includes a support substrate 4B and the piezoelectric layer 6. The piezoelectric layer 6 is directly provided on the support substrate 4B. More specifically, the support substrate 4B includes a recessed portion 4c. The piezoelectric layer 6 is provided on the support substrate 4B so as to cover the recessed portion 4c. As a result, a hollow portion is provided in the piezoelectric substrate 2B. The hollow portion overlaps at least a portion of the IDT electrode 8 in a plan view.

In the first example embodiment, by changing the duty ratio according to the excitation angle θ_{C_prop}, the resonant frequencies or the anti-resonant frequencies of all the excitation portions match or substantially match each other. However, the parameters such as the electrode finger pitch, the thickness of the electrode finger, the thickness of the piezoelectric layer, and the thickness of the intermediate layer in the piezoelectric substrate, which affect the frequency, may be changed according to the excitation angle θ_{C_prop}, without being limited to the duty ratio. In a case where a dielectric film is provided on the piezoelectric substrate to cover the IDT electrode, the thickness of the dielectric film may be changed according to the excitation angle θ_{C_prop}. A plurality of the parameters among the above parameters may be changed according to the excitation angle θ_{C_prop}. Even in these cases, the resonant frequencies or the anti-resonant frequencies can match or substantially match each other in all the excitation portions.

In the first example embodiment, the shapes of all the portions of the first electrode finger 16 and the second electrode finger 17 are curved. As a result, the unnecessary waves can be further reduced or prevented. However, the shapes of the first electrode finger 16 and the second electrode finger 17 need not necessarily be curved in all portions. The first electrode finger 16 and the second electrode finger 17 may include a portion having a linear shape.

However, as in the first example embodiment, it is particularly preferable that the shapes of the first electrode finger 16 and the second electrode finger 17 in a plan view are the shapes of the circular arcs. Alternatively, it is particularly preferable that the shapes of the first electrode finger 16 and the second electrode finger 17 in a plan view are the shapes of the elliptical arcs. In these cases, it is possible to more effectively reduce or prevent the unnecessary wave outside the pass band and the transverse mode.

The duty ratio including the offset electrode located on the extension line of the excitation portion, the center-to-center distance between the offset electrode and the electrode finger, and the thickness of the offset electrode may also be changed according to the excitation angle θ_{C_prop} of the excitation portion, similar to the parameters of the electrode finger.

Hereinafter, an example in which the other than the duty ratio is changed according to the excitation angle θ_{C_prop} will be described. In each of the following examples, since the shape of the IDT electrode is different from that of the first example embodiment, the shape of the reflector is also different from that of the first example embodiment.

FIG. 16 is a schematic plan view of an acoustic wave device according to a second example embodiment.

The present example embodiment is different from the first example embodiment in that the shapes of the plurality of electrode fingers in a plan view are the shapes of the elliptical arcs. The present example embodiment is different from the first example embodiment in that the duty ratio is constant and the electrode finger pitch is not constant in the IDT electrode 28. Except for the above points, the acoustic wave device according to the present example embodiment has the same configuration as the acoustic wave device 1 according to the first example embodiment.

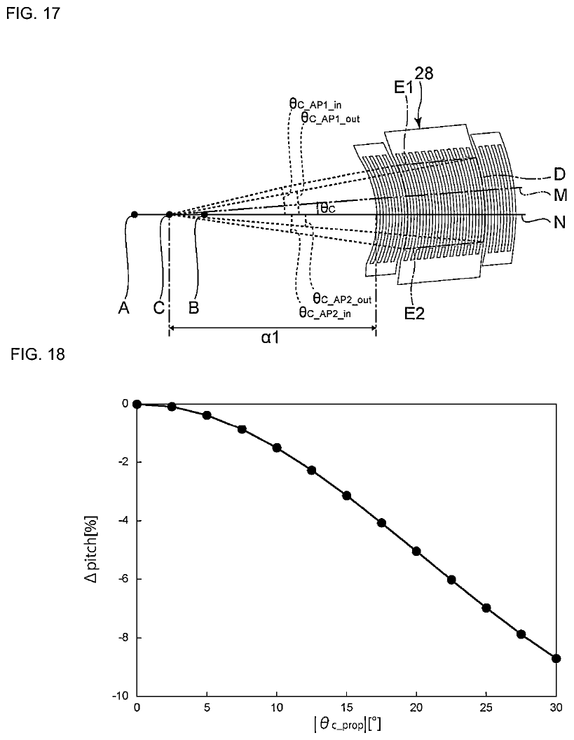

The shapes of the plurality of electrode fingers in a plan view are the shapes of the elliptical arcs. In this case, the shapes of the plurality of electrode fingers in a plan view are the respective shapes corresponding to the elliptical arcs of a plurality of ellipses having the same center of gravity. More specifically, as shown in FIG. 17, a midpoint of the focal point A and the focal point B is the center of gravity. The center of gravity is the fixed point C. In the present example embodiment, the elliptical coefficient α2/α1 of the shapes of the plurality of electrode fingers in a plan view is α2/α1<about 1, for example. More specifically, α2/α1=about 0.72, for example. However, the elliptical coefficient α2/α1 is not limited thereto.

In the present example embodiment, similar to the first example embodiment, a straight line connecting the fixed point C and the tip end of the second electrode finger is not parallel to the first envelope E1. Therefore, θ_{C_AP1_in}≠θ_{C_AP1_out}. A straight line connecting the fixed point C and the tip end of the first electrode finger is not parallel to the second envelope E2. Therefore, θ_{C_AP2_in}≠θ_{C_AP2_out}. As a result, it is possible to reduce or prevent the unnecessary wave outside the pass band and the transverse mode.

As described above, in the IDT electrode 28, the duty ratio is constant. Specifically, the duty ratio is about 0.5, for example. In the present example embodiment, the reference line N is a straight line passing through the excitation portion having the widest electrode finger pitch among all the excitation portions. The larger the absolute value of the excitation angle |θ_{C_prop}|, the narrower the electrode finger pitch. As a result, the resonant frequencies or the anti-resonant frequencies match or substantially match each other in all the excitation portions. Hereinafter, a relationship between the absolute value of the excitation angle |θ_{C_prop}| and the electrode finger pitch will be specifically described. Here, the electrode finger pitch in the excitation portion in which the excitation angle θ_{C_prop} is 0° is denoted by p0, the electrode finger pitch of any portion is denoted by p1, and {(p1−p0)/p0}×100 [%] is defined as the change rate of the electrode finger pitch Δpitch [%].

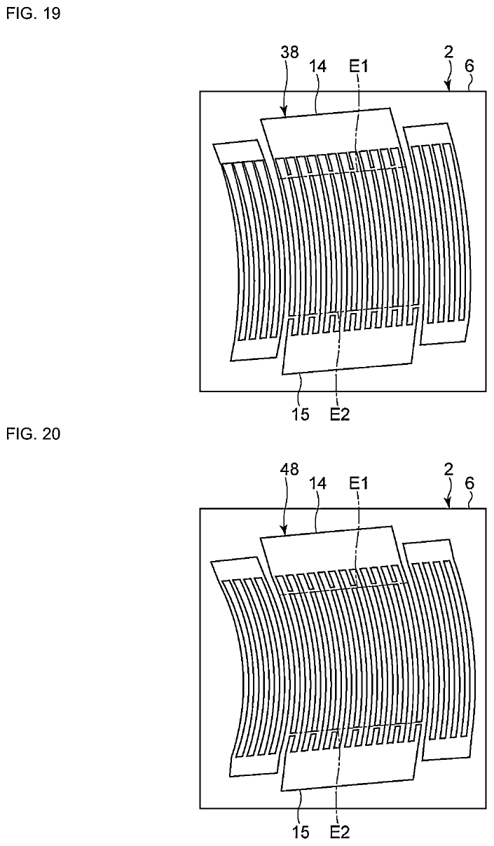

FIG. 18 is a graph showing a relationship between an absolute value of an excitation angle |θ_{C_prop}| and a rate of change Δpitch of an electrode finger pitch of the IDT electrode in the second example embodiment.

As shown in FIG. 18, in the present example embodiment, in the excitation portion in which the excitation angle θ_{C_prop} in the IDT electrode 28 is 0°, the Δpitch is 0%. The larger the absolute value of the excitation angle | θ_{C_prop}|, the larger Δpitch in the negative direction. That is, the larger the absolute value of the excitation angle |θ_{C_prop}|, the narrower the electrode finger pitch.

In the present example embodiment as well, similar to the first example embodiment, a straight line connecting the fixed point C and the tip end of the second electrode finger is not parallel to the first envelope E1. Therefore, θ_{C_AP1_in}≠θ_{C_AP1_out}. A straight line connecting the fixed point C and the tip end of the first electrode finger is not parallel to the second envelope E2. In other words, the straight line passing through the fixed point C and the first envelope E1 is not parallel to the first envelope E1, and the straight line passing through the fixed point C and the second envelope E2 is not parallel to the second envelope E2. As a result, it is possible to reduce or prevent the unnecessary wave outside the pass band and the transverse mode.

Furthermore, non-limiting examples of the design parameters of the acoustic wave device of the present example embodiment will be described below.
Elliptical coefficient α2/α1 in the shape of the electrode finger: 0.72
First inner side portion intersection angle θ_{C_AP1_in}: 9.6°
First outer side portion intersection angle θ_{C_AP1_out}: 7.5°
Second inner side portion intersection angle θ_{C_AP2_in}: −8.2°
Second outer side portion intersection angle θ_{C_AP2_out}: −5°
Longest wavelength λ: 2 μm
Electrode finger pitch: 1 μm in the excitation portion in which the excitation angle θ_{C_prop} is 0°
Duty Ratio: 0.5
Busbar inclination angle of the first busbar 14 and the second busbar 15: 2.5°
Length of the first offset electrode and the second offset electrode: 3.5λ

The relationship between the electrode finger pitch and the frequency of each mode varies depending on the reverse-velocity surface of the piezoelectric substrate. Therefore, depending on the configuration of the piezoelectric substrate or the configuration on the piezoelectric substrate, when the larger the absolute value of the excitation angle |θ_{C_prop}|, the wider the electrode finger pitch, the resonant frequencies or the anti-resonant frequencies may match or substantially match each other in all the excitation portions. In this case, among all the excitation portions, the reference line N is a straight line passing through the excitation portion having the narrowest electrode finger pitch and the fixed point C. Examples thereof include an acoustic wave device in which an IDT electrode provided on a substrate including only LiNbO₃ having a rotation Y-cut−4° X propagation is embedded in a SiO₂ film having a thick thickness. Alternatively, in the excitation portion in which the excitation angle θ_{C_prop} through which the reference line N passes is 0°, the value of the electrode finger pitch is not necessarily maximum or minimum.

FIG. 19 is a schematic plan view of an acoustic wave device according to a third example embodiment.

The present example embodiment is different from the first example embodiment in that the electrode finger pitch is not constant and an elliptical coefficient α2/α1 is larger than 1 in the IDT electrode 38. Except for the above points, the acoustic wave device according to the present example embodiment has the same configuration as the acoustic wave device 1 according to the first example embodiment. In the present example embodiment, both the duty ratio and the electrode finger pitch are not constant.

More specifically, among all the excitation portions, in the present example embodiment, the straight line passing through the excitation portion having the narrowest electrode finger pitch and the fixed point C is the reference line N. At the same time, among all the excitation portions, the straight line passing through the excitation portion having the largest duty ratio, and the fixed point C is the reference line N. The larger the absolute value of the excitation angle |θ_{C_prop}|, the wider the electrode finger pitch. The larger the absolute value of the excitation angle |θ_{C_prop}|, the smaller the duty ratio. As a result, the resonant frequencies or the anti-resonant frequencies match or substantially match each other in all the excitation portions. In the present example embodiment, similar to the first example embodiment, the straight line passing through the fixed point C and the first envelope E1 is not parallel to the first envelope E1, and the straight line passing through the fixed point C and the second envelope E2 is not parallel to the second envelope E2. As a result, it is possible to reduce or prevent the unnecessary wave outside the pass band and the transverse mode.

In the IDT electrode 38, the elliptical coefficient α2/α1 in the shapes of the plurality of electrode fingers is larger than 1. As a result, it is possible to suppress the response at an upper end of a stop band and to increase a value of a fractional stop band width. Details will be described below. The stop band is a region in which the wavelength of the acoustic wave is constant when the acoustic wave is confined to the metal grating having a periodic structure. The fractional stop band width is a value obtained by dividing the band width of the stop band by the resonant frequency. The upper end of the stop band is an end portion of the stop band on the higher band side. The band width of the stop band is a difference between the frequency at the upper end of the stop band and the resonant frequency.

In a case where the elliptical coefficient α2/α1 is larger than 1, the frequency at the upper end of the stop band is dispersed. As a result, it is possible to reduce or prevent the response of the frequency at the upper end of the stop band. In addition, a dimension of the intersection region in a direction in which the first busbar 14 and the second busbar 15 face each other is larger than a dimension of the t intersection region in a direction orthogonal to the direction. Therefore, the curvature of the shapes of the plurality of electrode fingers in a plan view approaches 0. In this case, the band width of the stop band is widened. Therefore, the value of the fractional stop band width can be increased.

Furthermore, in the present example embodiment, by using only the duty ratio, the value of the fractional band width can be made larger than in a case where the frequencies of each of the excitation portions match or substantially match each other. The fractional band width is represented by |fa−fr|/fr when the resonant frequency is defined as fr and the anti-resonant frequency is defined as fa.

Non-limiting examples of the design parameters of the acoustic wave device according to the present example embodiment will be described below.

Number of pairs of electrode fingers of IDT electrode: 60 pairs
Elliptical coefficient α2/α1 in the shape of the electrode finger: 1.1
First inner side portion intersection angle θ_{C_AP1_in}: 11.8°
First outer side portion intersection angle θ_{C_AP1_out}: 9.1°
Second inner side portion intersection angle θ_{C_AP2_in}: −6.1°
Second outer side portion intersection angle θ_{C_AP2_out}: −3.5°
Duty ratio: 0.5 in the excitation portion in which the excitation angle θ_{C_prop} is 0°
Busbar inclination angle of the first busbar 14 and the second busbar 15: 2.5°
Length of the first offset electrode and the second offset electrode: 3.5λ
Number of pairs of electrode fingers of reflector: 20 pairs

FIG. 20 is a schematic plan view of an acoustic wave device according to a fourth example embodiment.

The present example embodiment is different from the first example embodiment in that the electrode finger pitch is not constant and an elliptical coefficient α2/α1 is smaller than 1 in the IDT electrode 48. Except for the above points, the acoustic wave device according to the present example embodiment has the same configuration as the acoustic wave device 1 according to the first example embodiment. In the present example embodiment, both the duty ratio and the electrode finger pitch are not constant.

More specifically, in the present example embodiment, among all the excitation portions, the straight line passing through the excitation portion having the widest electrode finger pitch and the fixed point C is the reference line N. At the same time, among all the excitation portions, the straight line passing through the excitation portion having the largest duty ratio, and the fixed point C is the reference line N. The larger the absolute value of the excitation angle |θ_{C_prop}|, the narrower the electrode finger pitch. The larger the absolute value of the excitation angle |θ_{C_prop}|, the smaller the duty ratio. As a result, the resonant frequencies or the anti-resonant frequencies match or substantially match each other in all the excitation portions. In the present example embodiment, similar to the first example embodiment, the straight line passing through the fixed point C and the first envelope E1 is not parallel to the first envelope E1, and the straight line passing through the fixed point C and the second envelope E2 is not parallel to the second envelope E2. As a result, it is possible to reduce or prevent the unnecessary wave outside the pass band and the transverse mode.

In the IDT electrode 48, the elliptical coefficient α2/α1 of the shapes of the plurality of electrode fingers in a plan view is smaller than 1. As a result, it is possible to suppress the response at the upper end of the stop band and to increase the value of the fractional stop band width. Details will be described below.

In a case where the elliptical coefficient α2/α1 is smaller than 1, the frequency at the upper end of the stop band is dispersed. As a result, it is possible to reduce or prevent the response of the frequency at the upper end of the stop band. In addition, the dimension of the intersection region in a direction in which the first busbar 14 and the second busbar 15 face each other is smaller than the dimension of the intersection region in a direction orthogonal to the direction. Therefore, the curvature is larger than that in a case where the shapes of the plurality of electrode fingers in a plan view are the circular arc shapes. In this case, an interval between the frequency at which the main mode occurs and the frequency at which the unnecessary wave occurs is widened. Therefore, the unnecessary waves can be effectively reduced or prevented. In addition to the above configuration, the frequencies of the excitation portions match or substantially match each other by both the duty ratio and the electrode finger pitch. As a result, by using only the duty ratio, unnecessary waves can be reduced or prevented as compared with a case where the frequencies of each of the excitation portions match or substantially match each other.

Furthermore, in the present example embodiment, by using only the duty ratio, the value of the fractional band width can be made smaller than in a case where the frequencies of each of the excitation portions match or substantially match each other.

Non-limiting examples of the design parameters of the acoustic wave device according to the present example embodiment will be described below.
Number of pairs of electrode fingers of IDT electrode: 60 pairs
Elliptical coefficient α2/α1 in the shape of the electrode finger: 0.9
First inner side portion intersection angle θ_{C_AP1_in}: 10.8°
First outer side portion intersection angle θ_{C_AP1_Out}: 8.1°
Second inner side portion intersection angle θ_{C_AP2_in}: −7.5°
Second outer side portion intersection angle θ_{C_AP2_out}: −4.1°
Duty ratio: 0.5 in the excitation portion in which the excitation angle θ_{C_prop} is 0°
Busbar inclination angle of the first busbar 14 and the second busbar 15: 2.5°
Length of the first offset electrode and the second offset electrode: 3.5λ
Number of pairs of electrode fingers of reflector: 20 pairs

In the first to fourth example embodiments, by adjusting the duty ratio or the electrode finger pitch, the resonant frequencies or anti-resonant the frequencies match or substantially match each other in all the excitation portions. However, the resonant frequencies or the anti-resonant frequencies of all the excitation portions may match or substantially match each other by adjusting the thicknesses of the plurality of electrode fingers. The example will be described with reference to a fifth example embodiment.

The fifth example embodiment is different from the first example embodiment in that the duty ratio is constant and the thickness of the plurality of electrode fingers is not constant in the IDT electrode. Except for the above points, the acoustic wave device according to the present example embodiment has the same configuration as the acoustic wave device 1 according to the first example embodiment.

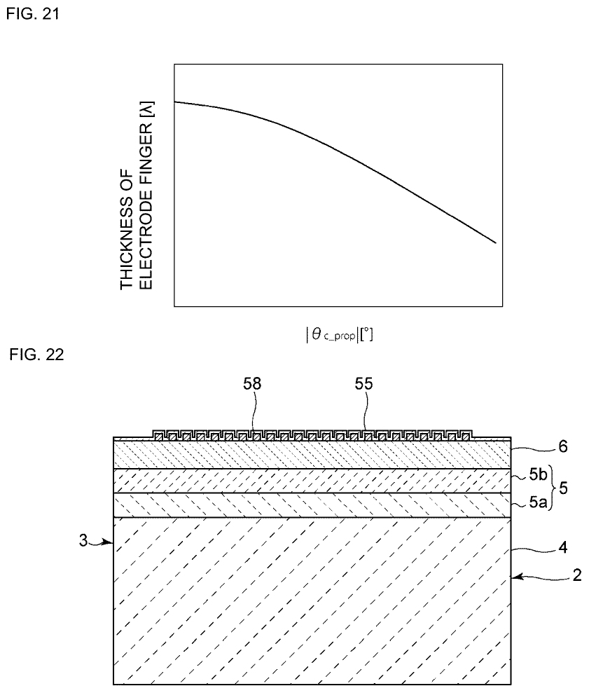

FIG. 21 is a graph showing a relationship between an absolute value of an excitation angle |θ_{C_prop}| and a thickness of an electrode finger of the IDT electrode in the fifth example embodiment.

In the fifth example embodiment, among all the excitation portions, the straight line passing through the excitation portion having largest thicknesses of the first electrode finger and the second electrode finger, and the fixed point C is the reference line N. As shown in FIG. 21, the larger the absolute value of the excitation angle |θ_{C_prop}| in the IDT electrode, the smaller the thicknesses of the first electrode finger and the second electrode finger. As a result, the resonant frequencies of all the excitation portions match or substantially match each other. Similarly, the anti-resonant frequencies of all the excitation portions can also match or substantially match each other.

In addition, in the fifth example embodiment, similar to the first example embodiment, the straight line passing through the fixed point C and the first envelope E1 is not parallel to the first envelope E1, and the straight line passing through the fixed point C and the second envelope E2 is not parallel to the second envelope E2. As a result, it is possible to reduce or prevent the unnecessary wave outside the pass band and the transverse mode.

The relationship between the thicknesses of the first electrode finger and the second electrode finger and the frequency of each of the modes varies depending on the reverse-velocity surface of the piezoelectric substrate. Therefore, depending on the configuration of the piezoelectric substrate or the configuration on the piezoelectric substrate, when the larger the absolute value of the excitation angle |θ_{C_prop}|, the larger the thicknesses of the first electrode finger and the second electrode finger, the resonant frequencies or the anti-resonant frequencies may match or substantially match each other in all the excitation portions. In this case, among all the excitation portions, the straight line passing through the excitation portion with smallest thicknesses of the first electrode finger and the second electrode finger, and the fixed point C is the reference line N. Examples thereof include an acoustic wave device in which an IDT electrode provided on a substrate including only LiNbO₃ having a rotation Y-cut−4° X propagation is embedded in a SiO₂ film having a thick thickness. Alternatively, in the excitation portion in which the reference line N passes and the excitation angle θ_{C_prop} is 0°, the values of the thicknesses of the first electrode finger and the second electrode finger are not necessarily maximum or minimum.

In the first to fifth example embodiments, the resonant frequencies or the anti-resonant frequencies of all the excitation portions match or substantially match each other due to the configuration of the IDT electrode. However, the resonant frequencies or the anti-resonant frequencies of all the excitation portions may match or substantially match each other by adjusting the thickness of the dielectric film covering the IDT electrode. This example will be described with reference to a sixth example embodiment and a modification example thereof.

FIG. 22 is a schematic elevational cross-sectional view of an acoustic wave device according to a sixth example embodiment. FIG. 22 is a schematic cross-sectional view along the reference line N.

The present example embodiment is different from the first example embodiment in that the duty ratio is constant in the IDT electrode 58. The present example embodiment is also different from the first example embodiment in that the dielectric film 55 is provided on the piezoelectric layer 6 to cover the IDT electrode 58. Except for the above points, the acoustic wave device according to the present example embodiment has the same configuration as the acoustic wave device 1 according to the first example embodiment.

The acoustic velocity of the transversal wave propagating through the dielectric film 55 of the present example embodiment is lower than the acoustic velocity of the main mode propagating through the dielectric film 55. The thickness of the dielectric film 55 varies depending on the excitation angle θ_{C_prop} of the excitation portion of the IDT electrode 58 covered with the dielectric film 55.

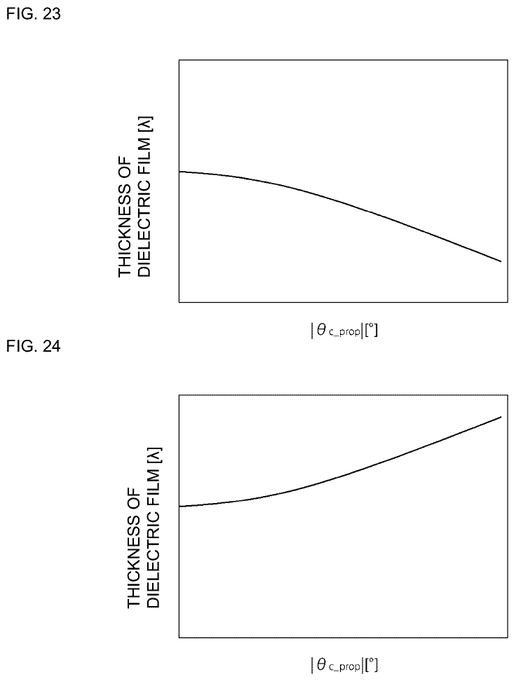

FIG. 23 is a graph showing a relationship between the absolute value of the excitation angle |θ_{C_prop}| in the excitation portion of the IDT electrode covered with the dielectric film and the thickness of the dielectric film in the sixth example embodiment.

In the present example embodiment, among all the excitation portions, the straight line passing through the excitation portion in which the portion having the largest thickness in the dielectric film 55 is located and the fixed point C is the reference line N. As shown in FIG. 23, in the present example embodiment, the larger the absolute value of the excitation angle |θ_{C_prop}| in the excitation portion of the IDT electrode 58 covered with the dielectric film 55, the smaller the thickness of the dielectric film 55. As a result, the resonant frequencies or the anti-resonant frequencies of all the excitation portions match or substantially match each other.

In addition, in the present example embodiment, similar to the first example embodiment, the straight line passing through the fixed point C and the first envelope E1 is not parallel to the first envelope E1, and the straight line passing through the fixed point C and the second envelope E2 is not parallel to the second envelope E2. As a result, it is possible to reduce or prevent the unnecessary wave outside the pass band and the transverse mode.

In the sixth example embodiment, the acoustic velocity of the transversal wave propagating through the dielectric film 55 is lower than the acoustic velocity of the main mode propagating through the dielectric film 55. However, the relationship of the acoustic velocity of the wave propagating through the dielectric film is not limited to the above-described relationship. A modification example of the sixth example embodiment in which only the acoustic velocity of the transversal wave propagating through the dielectric film is different from that of the sixth example embodiment will be described below.

In the modification example of the example embodiment, the acoustic velocity of the transversal wave propagating through the dielectric film is higher than the acoustic velocity of the main mode propagating through the dielectric film. In the present modification example, a relationship between the absolute value of the excitation angle |θ_{C_prop}| in the excitation portion in the IDT electrode covered with the dielectric film and the thickness of the dielectric film is shown in FIG. 24. More specifically, in the present modification example, among all the excitation portions, the straight line passing through the excitation portion in which the portion having the smallest thickness in the dielectric film is located and the fixed point C is the reference line N. The larger the absolute value of the excitation angle |θ_{C_prop}| in the excitation portion of the IDT electrode covered with the dielectric film, the larger the thickness of the dielectric film. As a result, the resonant frequencies or the anti-resonant frequencies of all the excitation portions match or substantially match each other. In the present modification example, similar to the sixth example embodiment, it is possible to reduce or prevent the unnecessary wave outside the pass band and the transverse mode.

Depending on the configuration of the piezoelectric substrate, the value of the thickness of the portion in which the reference line N passes among the thicknesses of the portions covering the excitation portion in the dielectric film is not necessarily maximum or minimum.

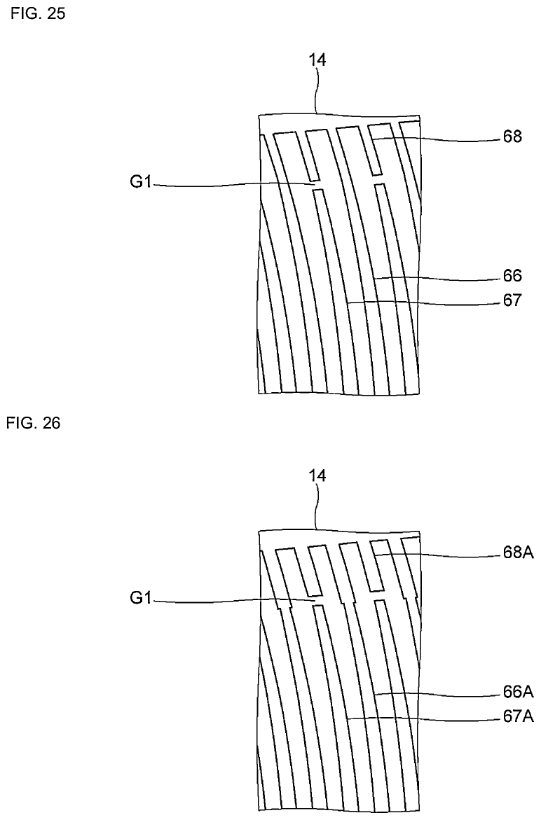

FIG. 25 is a schematic plan view showing the vicinity of a gap on the first busbar side of the IDT electrode in the seventh example embodiment.

The present example embodiment is different from the first example embodiment in that by changing at least the parameter other than the duty ratio according to the excitation angle θ_{C_prop}, the resonant frequencies or the anti-resonant frequencies of all the excitation portions match or substantially match each other. The duty ratio in a portion in which the tip end portions of the plurality of first electrode fingers 66 are arranged is constant. Similarly, the duty ratio in a portion in which the tip end portions of the plurality of second electrode fingers 67 are arranged is constant. In the present example embodiment, the configuration of the region between the intersection region and the first busbar 14 and the region between the intersection region and the second busbar is also different from that of the first example embodiment. Except for the above points, the acoustic wave device according to the present example embodiment has the same configuration as the acoustic wave device 1 according to the first example embodiment.

The widths of the plurality of first offset electrodes 68 are constant. The widths of the plurality of first electrode fingers 66 are also constant in the region in the outer side portion of the intersection region. More specifically, the widths of the plurality of first offset electrodes 68 are the same as the widths of the tip end portions of the plurality of second electrode fingers 67. The widths of the plurality of first electrode fingers 66 are the same as the widths of the plurality of first offset electrodes 68 in the region in the outer side portion of the intersection region. The shapes of the plurality of first offset electrodes 68 in a plan view are curved. The shapes of the plurality of first electrode fingers 66 in the region in the outer side portion of the intersection region in a plan view are also curved. The duty ratio in the region between the intersection region and the first busbar 14 is the same as the duty ratio in the portion in which the tip end portions of the plurality of second electrode fingers 67 are arranged.

Although not shown, the widths of the plurality of second offset electrodes are the same as the widths of the tip end portions of the plurality of first electrode fingers 66 and are constant. The widths of the plurality of second electrode fingers 67 are the same as the widths of the plurality of second offset electrodes in the region in the outer side portion of the intersection region. The shapes of the plurality of second offset electrodes in a plan view are curved. The shapes of the plurality of second electrode fingers 67 in the region in the outer side portion of the intersection region in a plan view are also curved. The duty ratio in the region between the intersection region and the second busbar is the same as the duty ratio in the portion in which the tip end portions of the plurality of first electrode fingers 66 are arranged.

In the present example embodiment, the widths of the plurality of first offset electrodes 68 and the plurality of first electrode fingers 66 are not narrowed in the region between the intersection region and the first busbar 14. The widths of the plurality of second offset electrodes and the plurality of second electrode fingers 67 are also not narrowed in the region between the intersection region and the second busbar. As a result, the series resistance can be reduced.

In addition, in the present example embodiment, similar to the first example embodiment, the straight line passing through the fixed point C and the first envelope E1 is not parallel to the first envelope E1, and the straight line passing through the fixed point C and the second envelope E2 is not parallel to the second envelope E2. As a result, it is possible to reduce or prevent the unnecessary wave outside the pass band and the transverse mode.

Hereinafter, a first modification example and a second modification example of the seventh example embodiment will be described, in which only the configurations of the region between the intersection region and the first busbar 14 and the region between the intersection region and the second busbar are different from those of the seventh example embodiment. In the first modification example and the second modification example, it is possible to reduce or prevent the unnecessary wave outside the pass band and the transverse mode and to reduce the series resistance, similar to the seventh example embodiment.

In the first modification example shown in FIG. 26, the widths of the plurality of first offset electrodes 68A are wider than the widths of the tip end portions of the plurality of second electrode fingers 67A. The widths of the plurality of first electrode fingers 66A are the same as the widths of the plurality of first offset electrodes 68A in the region in the outer side portion of the intersection region. Although not shown, the widths of the plurality of second offset electrodes are wider than the widths of the tip end portions of the plurality of first electrode fingers 66A. The widths of the plurality of second electrode fingers 67B are the same as the widths of the plurality of second offset electrodes in the region in the outer side portion of the intersection region.

Therefore, in the present modification example, the duty ratio in the region between the intersection region and the first busbar 14 is larger than the duty ratio in the portion in which the tip end portions of the plurality of second electrode fingers 67A are arranged. Similarly, the duty ratio in the region between the intersection region and the second busbar is larger than the duty ratio in the portion in which the tip end portions of the plurality of first electrode fingers 66A are arranged.

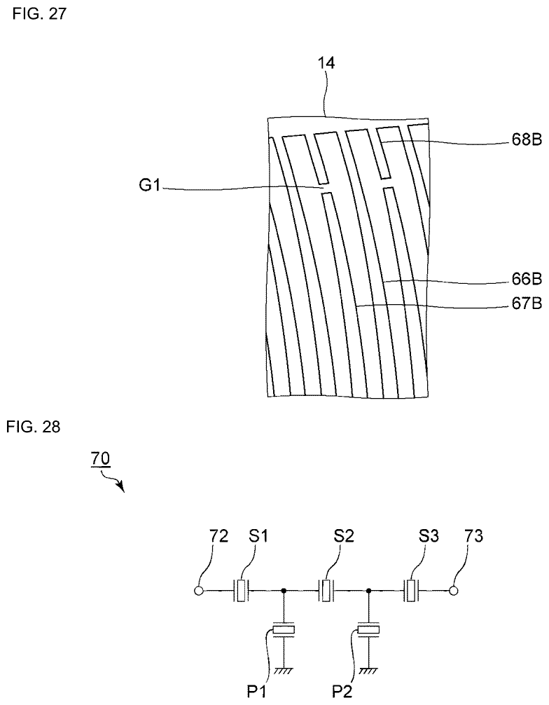

In the second modification example shown in FIG. 27, the shapes of the plurality of first offset electrodes 68B and the plurality of second offset electrodes in a plan view are linear. Similarly, in the present modification example, the shapes of the plurality of first electrode fingers 66B and the plurality of second electrode fingers 67B in a plan view are linear in the region in the outer side portion of the intersection region.

Acoustic wave devices according to various example embodiments of the present invention can be used, for example, in filter devices. Examples will be described below.

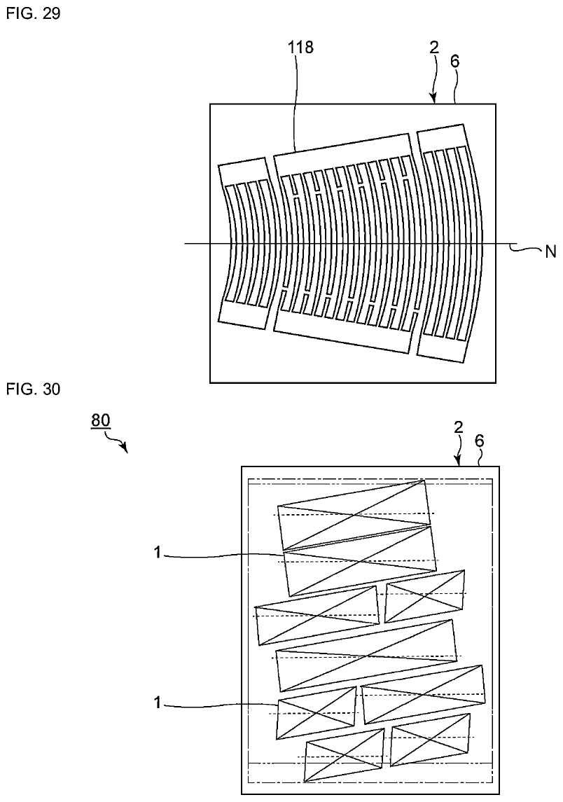

FIG. 28 is a circuit diagram of a filter device according to an eighth example embodiment.

The filter device 70 according to the present example embodiment is a ladder filter. The filter device 70 includes a first signal terminal 72, a second signal terminal 73, a plurality of series arm resonators, and a plurality of parallel arm resonators. In the filter device 70, all the series arm resonators and all the parallel arm resonators are acoustic wave resonators. Furthermore, all the series arm resonators and all the parallel arm resonators are the acoustic wave devices according to one or more example embodiments of the present invention. However, at least one acoustic wave resonator of the plurality of acoustic wave resonators of the filter device 70 may be one of the acoustic wave devices according to example embodiments of the present invention.

The first signal terminal 72 is an antenna terminal. The antenna terminal is connected to an antenna. However, the first signal terminal 72 need not necessarily be an antenna terminal. The first signal terminal 72 and the second signal terminal 73 may be configured as, for example, electrode pads, or may be configured as wirings.

Specifically, the plurality of series arm resonators of the present example embodiment are a series arm resonator S1, a series arm resonator S2, and a series arm resonator S3. The plurality of series arm resonators are connected in series to each other between the first signal terminal 72 and the second signal terminal 73. Specifically, the plurality of parallel arm resonators are a parallel arm resonator P1 and a parallel arm resonator P2. The parallel arm resonator P1 is connected between a connection point between the series arm resonator S1 and the series arm resonator S2, and a ground potential. The parallel arm resonator P2 is connected between a connection point between the series arm resonator S2 and the series arm resonator S3, and the ground potential. The circuit configuration of the filter device 70 is not limited to the above-described configuration. The filter device 70 may include, for example, a longitudinally coupled resonator-type acoustic wave filter.

The acoustic wave resonator in the filter device 70 is the acoustic wave device according to an example embodiment of the present invention. Therefore, in the acoustic wave resonator of the filter device 70, it is possible to suppress the transverse mode and reduce or prevent the unnecessary wave outside the pass band. As a result, it is also possible to reduce or prevent the unnecessary wave outside the pass band of the filter device 70.

Incidentally, for example, in the acoustic wave device of the reference example shown in FIG. 29, the sum of the absolute values of the busbar inclination angles of the first busbar and the second busbar in the IDT electrode 118 is larger than about 5°, for example. In a case where the acoustic wave device is used for the filter device, it is difficult to reduce the size of the filter device. On the other hand, for example, in the acoustic wave device 1 of the first example embodiment, the sum of the absolute values of the busbar inclination angles of the first busbar and the second busbar is about 5° or less, for example. As a result, in a case where the acoustic wave device 1 is used in the filter device, the size of the filter device can be further reduced. This will be described with reference to a ninth example embodiment and a modification example thereof.

FIG. 30 is a schematic plan view of a filter device according to a ninth example embodiment. In FIG. 30, the acoustic wave resonator is shown in a schematic view in which two diagonal lines are added to a square. The broken line in FIG. 30 corresponds to the reference line N in each acoustic wave resonator. The same applies to the schematic plan view other than FIG. 30.

In the present example embodiment, a plurality of acoustic wave resonators are configured on the piezoelectric substrate. Each acoustic wave resonator is the acoustic wave device 1 according to the first example embodiment. The sum of absolute values of inclination angles of the first busbar and the second busbar in each of the acoustic wave resonators is about 5° or less, for example. As a result, the plurality of acoustic wave resonators can be disposed such that the busbars of the adjacent acoustic wave resonators extend parallel or substantially parallel to each other. As a result, the area of the portion in which the plurality of acoustic wave resonators are configured can be reduced. Therefore, the size of the filter device 80 can be reduced.

The disposition of each acoustic wave resonator in the modification example of the ninth example embodiment shown in FIG. 31 corresponds to a disposition in which the flat orientation is rotated with respect to each acoustic wave resonator in the ninth example embodiment. The flat orientation is a reference in a direction of a wafer when manufacturing the acoustic wave device. The piezoelectric layer is formed by dividing a wafer. In the present modification example, each acoustic wave resonator can be disposed such that the end edge portion of the piezoelectric substrate and the busbar of each acoustic wave resonator extend in parallel or substantially in parallel. Therefore, the size of the filter device 80A can be effectively reduced.

A frame of the two-dot chain line shown in FIG. 30 and FIG. 31 indicates a portion in which the plurality of acoustic wave resonators are disposed in the modification example of the ninth example embodiment. In FIG. 30, a frame of a one-dot chain line indicates a portion in which the plurality of acoustic wave resonators are disposed in the ninth example embodiment. As shown in FIG. 30, it can be seen that the effect of reducing the size of the filter device is particularly high in the modification example.

In the ninth example embodiment and the modification example thereof, each acoustic wave resonator in the filter device is the acoustic wave device 1 according to the first example embodiment. Therefore, in each of the acoustic wave resonators of the filter device, it is possible to suppress the transverse mode and reduce or prevent the unnecessary wave outside the pass band. As a result, it is also possible to reduce or prevent the unnecessary wave outside the pass band of the filter device.

Incidentally, the curve in the shapes of the plurality of electrode fingers in a plan view in the acoustic wave device according to each of the above-described example embodiments is a smooth curve. The curve in the shapes of the plurality of electrode fingers in a plan view may be a shape formed by connecting straight lines having a minute size. The curve in the shapes of the plurality of electrode fingers in a plan view may be a shape in which a plurality of vertices are connected to each other by the curve. Alternatively, the curve in the shapes of the plurality of electrode fingers in a plan view need not necessarily be a smooth curve. This example is described as a sixth modification example of the first example embodiment.

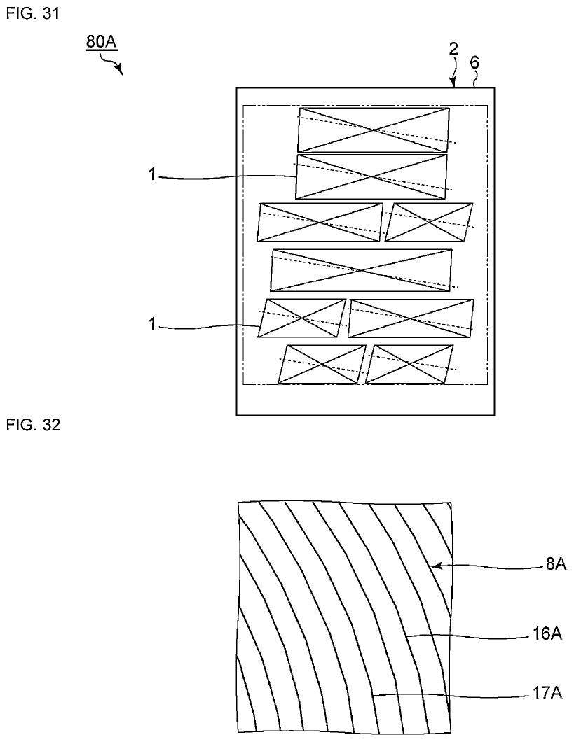

In the IDT electrode 8A in the sixth modification example shown in an enlarged manner in FIG. 32, the curve in the shape of each of the first electrode fingers 16A in a plan view is not a smooth curve. Specifically, the shape of each of the first electrode fingers 16A in a plan view is a shape formed by connecting the straight lines. The straight line in the shape is not a straight line having a minute size. More specifically, the length of the straight line in the shape is, for example, approximately several % of the total length of the first electrode finger 16A. However, in the shape, an angle formed between the connected straight lines is large, for example, approximately 160° or more and less than approximately 180°, for example. Therefore, the shape of each of the first electrode fingers 16A in a plan view is a shape that can be approximated to a curve.

The shape of each of the second electrode fingers 17A in a plan view is also the same as the shape of each of the first electrode fingers 16A in a plan view. In the present modification example, similar to the first example embodiment, it is possible to reduce or prevent the unnecessary wave outside the pass band and the transverse mode.

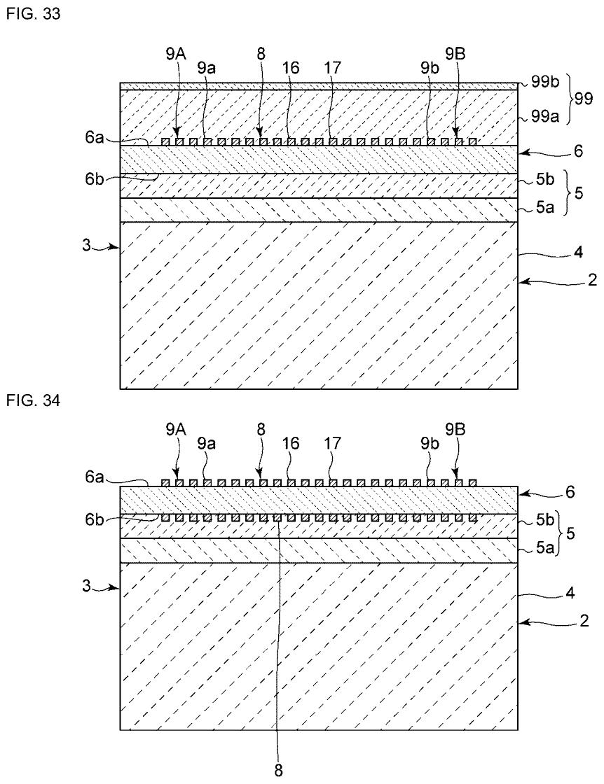

FIG. 33 is a schematic elevational cross-sectional view of an acoustic wave device according to a tenth example embodiment.

The present example embodiment is different from the first example embodiment in that the IDT electrode 8 is embedded in a protection film 99. Except for the above points, the acoustic wave device according to the present example embodiment has the same configuration as the acoustic wave device 1 according to the first example embodiment.

Specifically, the protection film 99 is provided on the piezoelectric layer 6 to cover the IDT electrode 8. The thickness of the protection film 99 is larger than the thickness of the IDT electrode 8. The IDT electrode 8 is embedded in the protection film 99. As a result, the IDT electrode 8 is unlikely to be damaged.

The protection film 99 includes a first protection layer 99a and a second protection layer 99b. The IDT electrode 8 is embedded in the first protection layer 99a. The second protection layer 99b is provided on the first protection layer 99a. In this manner, a plurality of advantageous effects can be achieved by the protection film 99. Specifically, in the present example embodiment, silicon oxide is used as the material of the first protection layer 99a. As a result, the absolute value of a temperature coefficient of frequency (TCF) in the acoustic wave device can be reduced. Therefore, the temperature characteristics of the acoustic wave device can be improved. Silicon nitride is used for the second protection layer 99b. As a result, the humidity resistance of the acoustic wave device can be improved.

In addition, in the present example embodiment, the IDT electrode 8 is also configured in the same manner as the first example embodiment. As a result, it is possible to reduce or prevent the unnecessary wave outside the pass band and the transverse mode.

The materials of the first protection layer 99a and the second protection layer 99b are not limited to the above-described example. The protection film 99 may be a single layer, or may be a multilayer body having three or more layers.

FIG. 34 is a schematic elevational cross-sectional view of an acoustic wave device according to an eleventh example embodiment.

The present example embodiment is different from the first example embodiment in that the IDT electrode 8 is provided on both main surfaces of the piezoelectric layer 6. Except for the above points, the acoustic wave device according to the present example embodiment has the same configuration as the acoustic wave device 1 according to the first example embodiment.

The piezoelectric layer 6 includes a first main surface 6a and a second main surface 6b. The first main surface 6a and the second main surface 6b face each other. It is noted that the piezoelectric layer 6 in each of the above-described example embodiments similarly has the first main surface 6a and the second main surface 6b. In each of the above-described example embodiments and the present example embodiment, the IDT electrode is provided on the first main surface 6a. In the present example embodiment, the IDT electrode 8 is also provided on the second main surface 6b. The IDT electrode 8 provided on the second main surface 6b is embedded in the second layer 5b of the intermediate layer 5.

The IDT electrode 8 provided on the first main surface 6a and the IDT electrode 8 provided on the second main surface 6b of the piezoelectric layer 6 face each other with the piezoelectric layer 6 interposed therebetween. In the acoustic wave device according to the present example embodiment, the IDT electrode 8 is configured in the same manner as the first example embodiment on the first main surface 6a. As a result, it is possible to reduce or prevent the unnecessary wave outside the pass band and the transverse mode.

For example, the IDT electrodes 8 provided on the first main surface 6a and the second main surface 6b of the piezoelectric layer 6 may have different design parameters.

Hereinafter, first to third modification examples of the eleventh example embodiment, which are different from the eleventh example embodiment in at least one of the configuration of the electrode provided on the second main surface of the piezoelectric layer and the multilayer structure of the piezoelectric substrate will be described. Even in the first to third modification examples, it is possible to reduce or prevent the unnecessary wave outside the pass band and the transverse mode, similar to the eleventh example embodiment.

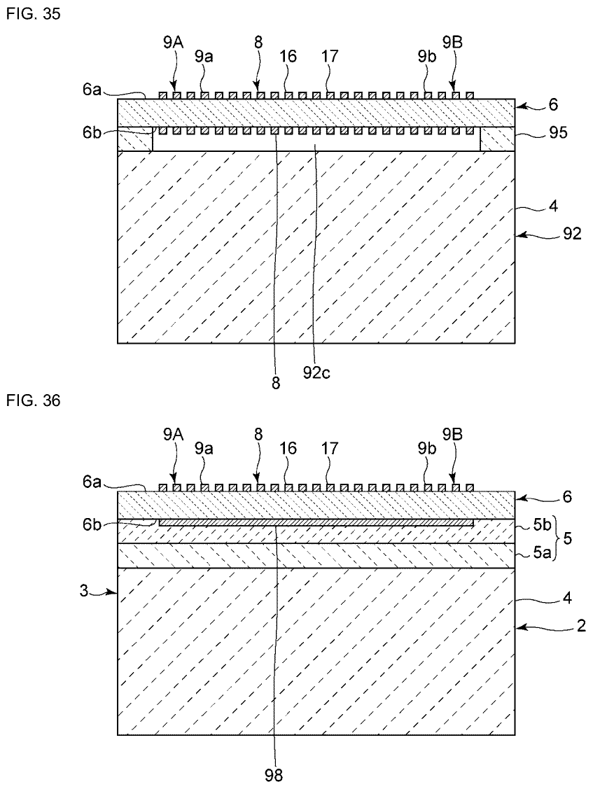

In the first modification example shown in FIG. 35, the layer configuration of the piezoelectric substrate 92 is different from that of the eleventh example embodiment. Specifically, the piezoelectric substrate 92 includes a support substrate 4, a dielectric layer 95, and a piezoelectric layer 6. A dielectric layer 95 is provided on the support substrate 4. The piezoelectric layer 6 is provided on the dielectric layer 95. In the present modification example, the dielectric layer 95 has a frame shape. That is, the dielectric layer 95 has a through-hole.

The support substrate 4 blocks one of the through-holes of the dielectric layer 95. The piezoelectric layer 6 blocks the other of the through-holes of the dielectric layer 95. As a result, a hollow portion 92c is formed in the piezoelectric substrate 92. A portion of the piezoelectric layer 6 and a portion of the support substrate 4 face each other with the hollow portion 92c interposed therebetween. The IDT electrode 8 provided on the second main surface 6b of the piezoelectric layer 6 is located inside the hollow portion 92c.

In the second modification example shown in FIG. 36, a plate-like electrode 98 is provided on the second main surface 6b of the piezoelectric layer 6. The IDT electrode 8 and the electrode 98 face each other with the piezoelectric layer 6 interposed therebetween.

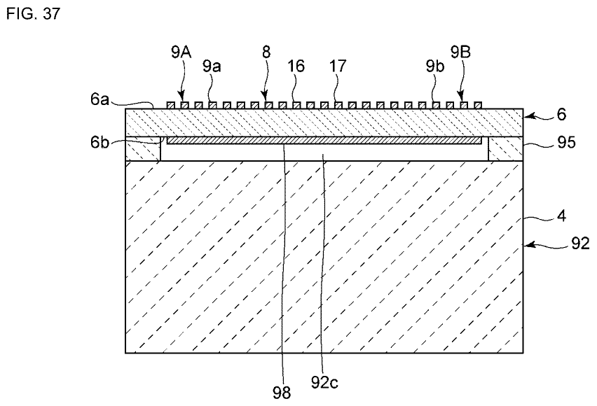

In the third modification example shown in FIG. 37, the piezoelectric substrate 92 is configured in the same manner as the first modification example, and the electrode 98 which is the same as that in the second modification example is provided on the second main surface 6b of the piezoelectric layer 6. The electrode 98 is located in the hollow portion 92c.

In the tenth example embodiment, the eleventh example embodiment, and each of the modification examples, an example of a case where the IDT electrode 8 has the same configuration as that in the first example embodiment is shown. However, each of the configurations of the tenth example embodiment, the eleventh example embodiment, and each modification example can also be adopted in a case where the configuration of the IDT electrode is the configuration of the present invention other than the first example embodiment.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
a piezoelectric substrate including a piezoelectric layer; and
an IDT electrode on the piezoelectric layer; wherein
the IDT electrode includes a first busbar and a second busbar facing each other, a plurality of first electrode fingers of which one end portion is connected to the first busbar, and a plurality of second electrode fingers of which one end portion is connected to the second busbar, and the plurality of first electrode fingers and the plurality of second electrode fingers are interdigitated with each other;
shapes of the plurality of first electrode fingers and the plurality of second electrode fingers in a plan view include a shape of a circular arc or an elliptical arc; and
when a virtual line formed by connecting tip ends of the plurality of second electrode fingers is defined as a first envelope, a virtual line formed by connecting tip ends of the plurality of first electrode fingers is defined as a second envelope, and a center of a circle including the circular arc or a midpoint of two focal points of an ellipse including the elliptical arc in the shapes of the first electrode fingers and the second electrode fingers is defined as a fixed point, a straight line connecting the fixed point and a tip end of a second electrode finger is not parallel to the first envelope, and a straight line connecting the fixed point and a tip end of a first electrode finger is not parallel to the second envelope.

2. The acoustic wave device according to claim 1, wherein in the IDT electrode, a region between the first envelope and the second envelope is an intersection region, and when a portion on any straight line passing through the fixed point in the intersection region is defined as an excitation portion, resonant frequencies or anti-resonant frequencies of all the excitation portions match or substantially match each other.

3. The acoustic wave device according to claim 2, wherein at least any one of a duty ratio, an electrode finger pitch, or thicknesses of the plurality of the first electrode fingers and the plurality of second electrode fingers is different between a plurality of the excitation portions such that the resonant frequencies or the anti-resonant frequencies of all the excitation portions match or substantially match each other.

4. The acoustic wave device according to claim 3, wherein in a case where a straight line passing through an excitation portion with a largest duty ratio among all the excitation portions and the fixed point is defined as a reference line, an angle formed between the straight line passing through the fixed point and the excitation portion, and the reference line is defined, and an excitation angle of an angle formed between an excitation direction of an acoustic wave at an intersection between the straight line passing through the fixed point and the excitation portion and the first electrode finger or the second electrode finger, and the reference line is defined, the larger an absolute value of the angle or the excitation angle, the smaller a duty ratio.

5. The acoustic wave device according to claim 3, wherein in a case where a straight line passing through an excitation portion with a smallest duty ratio among all the excitation portions, and the fixed point is defined as a reference line, an angle formed between the straight line passing through the fixed point and the excitation portion, and the reference line is defined, and an excitation angle of an angle formed between an excitation direction of an acoustic wave at an intersection between the straight line passing through the fixed point and the excitation portion and the first electrode finger or the second electrode finger, and the reference line is defined, the larger an absolute value of the angle or the excitation angle, the larger a duty ratio.

6. The acoustic wave device according to claim 3, wherein in a case where a straight line passing through an excitation portion with a widest electrode finger pitch among all the excitation portions, and the fixed point is defined as a reference line, an angle formed between the straight line passing through the fixed point and the excitation portion, and the reference line is defined, and an excitation angle of an angle formed between an excitation direction of an acoustic wave at an intersection between the straight line passing through the fixed point and the excitation portion and the first electrode finger or the second electrode finger, and the reference line is defined, the larger an absolute value of the angle or the excitation angle, the narrower an electrode finger pitch.

7. The acoustic wave device according to claim 3, wherein in a case where a straight line passing through an excitation portion with a narrowest electrode finger pitch among all the excitation portions, and the fixed point is defined as a reference line, an angle formed between the straight line passing through the fixed point and the excitation portion, and the reference line is defined, and an excitation angle of an angle formed between an excitation direction of an acoustic wave at an intersection between the straight line passing through the fixed point and the excitation portion and the first electrode finger or the second electrode finger, and the reference line is defined, the larger an absolute value of the angle or the excitation angle, the wider an electrode finger pitch.

8. The acoustic wave device according to claim 3, wherein in a case where a straight line passing through an excitation portion with largest thicknesses of the first electrode finger and the second electrode finger among all the excitation portions, and the fixed point is defined as a reference line, an angle formed between the straight line passing through the fixed point and the excitation portion, and the reference line is defined, and an excitation angle of an angle formed between an excitation direction of an acoustic wave at an intersection between the straight line passing through the fixed point and the excitation portion and the first electrode finger or the second electrode finger, and the reference line is defined, the larger an absolute value of the angle or the excitation angle, the smaller thicknesses of the first electrode finger and the second electrode finger.

9. The acoustic wave device according to claim 3, wherein in a case where a straight line passing through an excitation portion with smallest thicknesses of the first electrode finger and the second electrode finger among all the excitation portions, and the fixed point is defined as a reference line, an angle formed between the straight line passing through the fixed point and the excitation portion, and the reference line is defined, and an excitation angle of an angle formed between an excitation direction of an acoustic wave at an intersection between the straight line passing through the fixed point and the excitation portion and the first electrode finger or the second electrode finger, and the reference line is defined, the larger an absolute value of the angle or the excitation angle, the larger thicknesses of the first electrode finger and the second electrode finger.

10. The acoustic wave device according to claim 2, further comprising:
a dielectric film provided on the piezoelectric layer to cover the IDT electrode; wherein
thicknesses between portions provided on a plurality of the excitation portions in the dielectric film are different such that the resonant frequencies or the anti-resonant frequencies of all the excitation portions match or substantially match each other; and
in a case where a straight line passing through an excitation portion where a portion with a largest thickness in the dielectric film is located among all the excitation portions and the fixed point is defined as a reference line, an angle formed between the straight line passing through the fixed point and the excitation portion, and the reference line is defined, and an excitation angle of an angle formed between an excitation direction of an acoustic wave at an intersection between the straight line passing through the fixed point and the excitation portion and the first electrode finger or the second electrode finger, and the reference line is defined, the larger an absolute value of the angle or the excitation angle, the smaller a thickness of the dielectric film.

11. The acoustic wave device according to claim 2, further comprising:
a dielectric film provided on the piezoelectric layer to cover the IDT electrode; wherein
thicknesses between portions provided on a plurality of the excitation portions in the dielectric film are different such that the resonant frequencies or the anti-resonant frequencies of all the excitation portions match or substantially match each other; and
in a case where a straight line passing through an excitation portion where a portion with a smallest thickness in the dielectric film is located among all the excitation portions and the fixed point is defined as a reference line, an angle formed between the straight line passing through the fixed point and the excitation portion, and the reference line is defined, and an excitation angle of an angle formed between an excitation direction of an acoustic wave at an intersection between the straight line passing through the fixed point and the excitation portion and the first electrode finger or the second electrode finger, and the reference line is defined, the larger an absolute value of the angle or the excitation angle, the larger a thickness of the dielectric film.

12. The acoustic wave device according to claim 4, wherein
the piezoelectric layer includes a piezoelectric single crystal; and
a propagation axis of the piezoelectric layer and the propagation axis extend parallel or substantially parallel to each other.

13. The acoustic wave device according to claim 4, wherein when an angle formed between each of the first busbar and the second busbar, and the reference line is defined as a busbar inclination angle, a sum of absolute values of the busbar inclination angles of the first busbar and the second busbar is about 5° or less.

14. The acoustic wave device according to claim 3, wherein
the plurality of the excitation portions in which duty ratios are different from each other are provided such that the resonant frequencies or the anti-resonant frequencies of all the excitation portions match or substantially match each other;
the acoustic wave device further comprises a plurality of first offset electrodes and a plurality of second offset electrodes;
each of the plurality of first offset electrodes is connected to the first busbar, and each of the plurality of second offset electrodes is connected to the second busbar;
a tip end portion of the second electrode finger and a tip end portion of a first offset electrode face each other with a gap interposed, and a tip end portion of the first electrode finger and a tip end portion of a second offset electrode face each other with a gap interposed;
shapes of the plurality of first offset electrodes include a shape of a circular arc included in a circle with the fixed point as a center or an elliptical arc included in an ellipse with the fixed point as a midpoint of two focal points; and
a duty ratio of a portion including a portion provided with the first offset electrode on an extension line of any excitation portion and the excitation portion is constant.

15. The acoustic wave device according to claim 3, wherein
the plurality of the excitation portions in which duty ratios are different from each other are provided such that the resonant frequencies or the anti-resonant frequencies of all the excitation portions match or substantially match each other;
the acoustic wave device further comprises a plurality of first offset electrodes and a plurality of second offset electrodes;
each of the plurality of first offset electrodes is connected to the first busbar, and each of the plurality of second offset electrodes is connected to the second busbar;
a tip end portion of the second electrode finger and a tip end portion of a first offset electrode face each other with a gap interposed, and a tip end portion of the first electrode finger and a tip end portion of a second offset electrode face each other with a gap interposed;
shapes of the plurality of first offset electrodes include a shape of a circular arc included in a circle with the fixed point as a center or an elliptical arc included in an ellipse with the fixed point as a midpoint of two focal points; and
in a region between the first busbar or the second busbar and the intersection region, a duty ratio changes in one of a direction in which the duty ratio increases and a direction in which the duty ratio decreases with increasing proximity to the first busbar or the second busbar.

16. The acoustic wave device according to claim 1, further comprising:
a plurality of first offset electrodes; and
a plurality of second offset electrodes; wherein
each of the plurality of first offset electrodes is connected to the first busbar, and each of the plurality of second offset electrodes is connected to the second busbar;
a tip end portion of the second electrode finger and a tip end portion of a first offset electrode face each other with a gap interposed, and a tip end portion of the first electrode finger and a tip end portion of a second offset electrode face each other with a gap interposed;
shapes of the plurality of first offset electrodes include a shape of a circular arc included in a circle with the fixed point as a center or an elliptical arc included in an ellipse with the fixed point as a midpoint of two focal points; and
a width of each of the first offset electrodes is constant.

17. The acoustic wave device according to claim 1, further comprising:
a plurality of first offset electrodes; and
a plurality of second offset electrodes; wherein
each of the plurality of first offset electrodes is connected to the first busbar, and each of the plurality of second offset electrodes is connected to the second busbar;
a tip end portion of the second electrode finger and a tip end portion of a first offset electrode face each other with a gap interposed, a tip end portion of the first electrode finger and a tip end portion of a second offset electrode face each other with a gap interposed; and
the first offset electrode has a linear shape.

18. The acoustic wave device according to claim 1, wherein when α2/α1 is defined as an elliptical coefficient of shapes of the plurality of first electrode fingers and the plurality of second electrode fingers in a plan view, α2/α1>about 1.

19. The acoustic wave device according to claim 1, wherein when α2/α1 is defined as an elliptical coefficient of shapes of the plurality of first electrode fingers and the plurality of second electrode fingers in a plan view, α2/α1<about 1.

20. The acoustic wave device according to claim 1, wherein when α2/α1 is defined as an elliptical coefficient of shapes of the plurality of first electrode fingers and the plurality of second electrode fingers in a plan view, α2/α1=about 1.

21. The acoustic wave device according to claim 1, wherein
the piezoelectric substrate includes a support substrate; and
the piezoelectric layer is provided on the support substrate.

22. The acoustic wave device according to claim 21, wherein the piezoelectric substrate includes an intermediate layer between the support substrate and the piezoelectric layer.

23. The acoustic wave device according to claim 1, wherein the piezoelectric substrate includes only the piezoelectric layer.

24. A filter device comprising:
a plurality of acoustic wave resonators; wherein
at least one of the acoustic wave resonators is the acoustic wave device according to claim 1.
